(19) United States
(12) Patent Application Publication
(10) Pub. No.: US 2023/0258716 A1
(43) Pub. Date: Aug. 17, 2023

(54) TECHNIQUES TO PERFORM SEMICONDUCTOR TESTING

(71) Applicant: Intel Corporation, Santa Clara, CA (US)

(72) Inventors: Swadesh Choudhary, Mountain View, CA (US); Debendra Das Sharma, Saratoga, CA (US); Gerald Pasdast, San Jose, CA (US); Zuogo Wu, San Jose, CA (US); Narasimha Lanka, Dublin, CA (US); Lakshmipriya Seshan, Sunnyvale, CA (US)

(73) Assignee: Intel Corporation, Santa Clara, CA (US)

(21) Appl. No.: 18/129,315

(22) Filed: Mar. 31, 2023

Related U.S. Application Data
(60) Provisional application No. 63/484,692, filed on Feb. 13, 2023.

(51) Int. Cl. G01R 31/3183; G01R 31/317

(52) U.S. Cl. CPC G01R 31/318314; G01R 31/31712; G01R 31/31718

(57) ABSTRACT

Techniques to perform semiconductor testing are described. Test equipment may test a chiplet for compliance with a semiconductor specification. A test device may connect to a test package with a model chiplet and a device under test (DUT) chiplet. The model chiplet may comprise a known good model (KGM) of the semiconductor specification. The test device may use the model chiplet to test the DUT chiplet. Other embodiments are described and claimed.

### CROSS-REFERENCE TO RELATED APPLICATIONS

This application claims the benefit of U.S. Provisional Application No. 63/484,692 filed Feb. 13, 2023, entitled “UNIVERSAL CHIPLET INTERCONNECT EXPRESS (UCIe) COMPLIANCE TESTING AND INFRASTRUCTURE”, the contents of which is herein incorporated by reference in its entirety.

### BACKGROUND

Advances in semi-conductor processing and logic design have permitted an increase in the amount of logic that may be present on integrated circuit devices. As a corollary, computer system configurations have evolved from a single or multiple integrated circuits in a system to multiple cores, multiple hardware threads, and multiple logical processors present on individual integrated circuits, as well as other interfaces integrated within such processors. A processor or integrated circuit typically comprises a single physical processor die, where the processor die may include any number of cores, hardware threads, logical processors, interfaces, memory, controller hubs, etc.

As a result of the greater ability to fit more processing power in smaller packages, smaller computing devices have increased in popularity. Smartphones, tablets, ultrathin notebooks, and other user equipment have grown exponentially. However, these smaller devices are reliant on servers both for data storage and complex processing that exceeds the form factor. Consequently, the demand in the high-performance computing market (e.g. server space) has also increased. For instance, in modern servers, there is typically not only a single processor with multiple cores, but also multiple physical processors (also referred to as multiple sockets) to increase the computing power. But as the processing power grows along with the number of devices in a computing system, the communication between sockets and other devices becomes more critical.

In fact, interconnects have grown from more traditional multi-drop buses that primarily handled electrical communications to full blown interconnect architectures that facilitate fast communication. Unfortunately, as the demand for future processors to consume at even higher-rates corresponding demand is placed on the capabilities of existing interconnect architectures.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a first system in accordance with one embodiment.

FIG. 2 illustrates a second system in accordance with one embodiment.

FIG. 3 illustrates an interconnect stack in accordance with one embodiment.

FIG. 4 illustrates a top view of a model chiplet in accordance with one embodiment.

FIG. 5 illustrates a top view of a device under test (DUT) chiplet in accordance with one embodiment.

FIG. 6 illustrates a top view of a test package in accordance with one embodiment.

FIG. 7 illustrates a side view of a model chiplet in accordance with one embodiment.

FIG. 8 illustrates a side view of a model chiplet in accordance with one embodiment.

FIG. 9 illustrates a side view of a model chiplet in accordance with one embodiment.

FIG. 10 illustrates a side view of a DUT chiplet in accordance with one embodiment.

FIG. 11 illustrates an adapter in accordance with one embodiment.

FIG. 12 illustrates a standard package in accordance with one embodiment.

FIG. 13 illustrates a first advanced package in accordance with one embodiment.

FIG. 14 illustrates a second advanced package in accordance with one embodiment.

FIG. 15 illustrates a third advanced package in accordance with one embodiment.

FIG. 16 illustrates a third system in accordance with one embodiment.

FIG. 17 illustrates test device in accordance with one embodiment.

FIG. 18 illustrates logic for a DUT chiplet in accordance with one embodiment.

FIG. 19 illustrates logic for a model chiplet in accordance with one embodiment.

FIG. 20 illustrates a test system in accordance with one embodiment.

FIG. 21 illustrates a logic flow in accordance with one embodiment.

FIG. 22 illustrates computer-readable storage medium in accordance with one embodiment.

FIG. 23 illustrates a computing system in accordance with one embodiment.

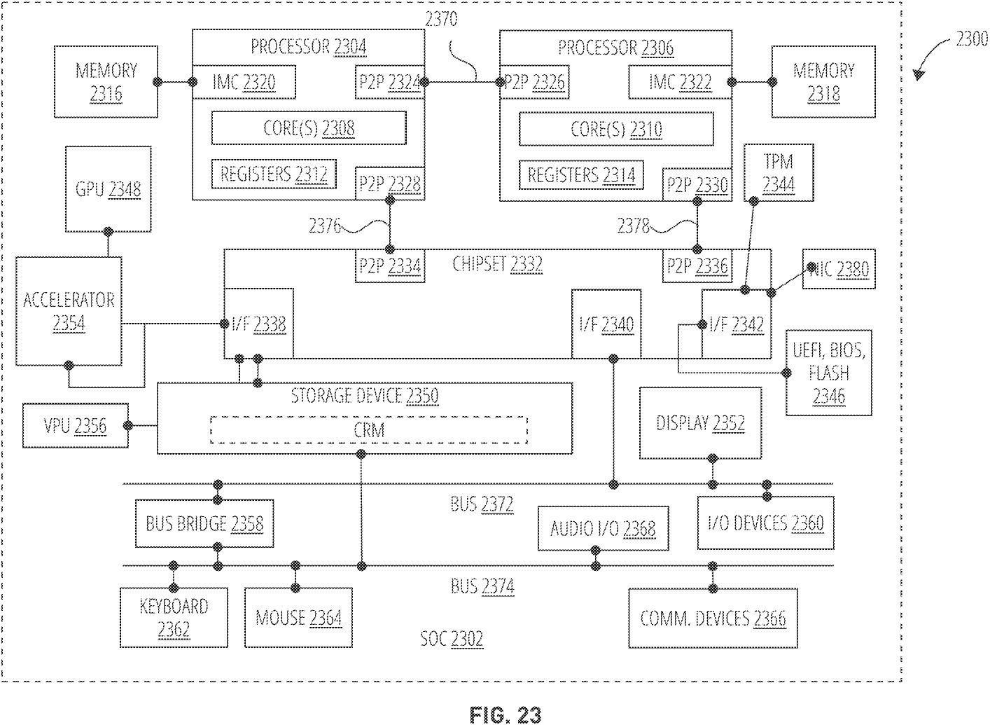

### DETAILED DESCRIPTION

Embodiments are generally directed to techniques to perform semiconductor testing for a device under test (DUT), such as a semiconductor die or a semiconductor package. A connection system is used to connect a DUT to automatic or manual test equipment. The test equipment then applies power to the DUT, supplies stimulus signals, then measures and evaluates the resulting outputs from the DUT. In this way, a tester may determine whether the particular DUT meets device specifications.

Some embodiments are directed to test equipment suitable to perform semiconductor testing for a semiconductor die, such as a chiplet that implements physical interconnects and related link protocols for an electronic system. The test equipment may determine whether the chiplet meets certain device specifications. In one embodiment, device specifications are defined by a Universal Chiplet Interconnect Express (UCIe™) specification promulgated by the UCIe Consortium, such as the UCIe specification, version 1.0, Feb. 17, 2022, along with any progeny, revisions and variants (collectively referred to as the “UCIe Specification”). Other device specifications may be used as well. Embodiments are not limited in this context.

Embodiments are directed to a testing framework for semiconductor testing. The testing framework may provide a hardware definition for performing compliance testing of an adapter and physical layer functionality as defined by the UCIe Specification. The testing framework may include test equipment which is a collection of hardware and software testing tools. The test equipment may include manual test equipment (MTE) or automated test equipment (ATE). In one embodiment, the testing framework may test a chiplet designed to operate in accordance with a particular design or model, such as the UCIe Specification. The test system may test UCIe hardware and software according to set of test criteria to measure compliance and interoperability against the test criteria. The test criteria may include, for example, one or more key performance indicators (KPIs) as defined by the UCIe Specification and other industry standards. The test system may provide test output to indicate whether the hardware or the software pass or fail testing in view of the testing criteria.

In some embodiments, the test equipment may include a model chiplet for semiconductor testing. The model chiplet may have a test interface, a set of model logic features and model test logic. The set of model logic features may comprise a known good model (KGM) for a set of logic features defined by a semiconductor specification, such as the UCIe Specification, among other specifications. The model test logic may receive a control signal from the test interface. The control signal may be sent by a test device. The model test logic may initiate testing of a DUT logic feature of a DUT chiplet in response to the control signal. The model test logic may send test information over an interconnect in response to the control signal. The interconnect may be, for example, a UCIe defined interconnect having an associated UCIe stack that includes a physical layer, adapter and protocol layer. The test information may be designed to test the DUT logic feature of the DUT chiplet. The DUT chiplet may have DUT test logic that receives the test information over the interconnect, generates response information, and sends the response information over the interconnect to the model chiplet. The model test logic may receive the response information over the interconnect in response to the test information. The response information may be associated with the DUT logic feature of the DUT chiplet. The model test logic may generate a measurement for the DUT logic feature based on the response information, and send the measurement for the DUT logic feature to the test interface for transport to the test device. The test device may compare the measurement to one or more evaluation criteria defined by the UCIe Specification. The test device may generate a test report with test results that indicates whether the DUT chiplet is compliant with the UCIe Specification. Other embodiments are described and claimed.

Embodiments provide a compliance methodology and capabilities for a KGM such as a model chiplet as well as an UGM such as a DUT chiplet. Embodiments provide a compliance setup, hardware definition, and hardware hooks for efficiently and effectively performing compliance testing of adapter and physical layer functionality as defined in the UCIe Specification. This provides significant advantages for semiconductor testing, such as reducing minimum area overhead in the DUT chiplet while still providing comprehensive coverage of a retry protocol and UCIe adapter capabilities as well as physical layer capabilities for compliance testing. Other advantages exist as well.

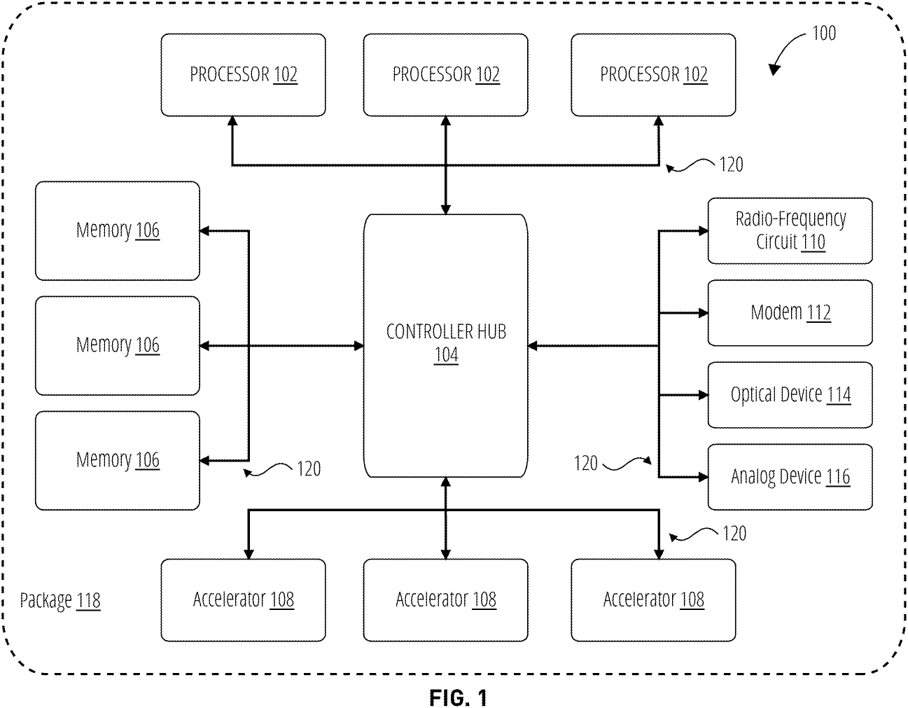

FIG. 1 illustrates an example of a system 100. System 100 may be an electronic system, such as a computing system, that implements one or more semiconductor dies or semiconductor packages. The semiconductor dies or semiconductor packages may implement one or more interconnects and associated link protocols defined by a semiconductor specification, such as the UCIe Specification, for example. UCIe is an open industry standard interconnect offering high-bandwidth, low-latency, power-efficient, and cost-effective on-package connectivity between chiplets.

System 100 illustrates an example of multiple semiconductor dies in a semiconductor package 118. System 100 illustrates a package level integration to deliver power-efficient and cost-effective performance. Components attached at the board level such as memory, accelerators, networking devices, modem, etc. can be integrated at the package level with applicability from hand-held to high-end servers with dies from multiple sources connected through different packaging options even on the same package.

In one embodiment, the semiconductor dies may be implemented, for example, as computing components of a computing system. Some of the semiconductor dies may be implemented as one or more chiplets. A chiplet is a tiny integrated circuit (IC) that contains a well-defined subset of functionality. It is designed to be combined with other chiplets on a substrate or an interposer in a single package. The substrate or interposer is an electrical interface routing between one socket or connection to another. The purpose of an interposer is to spread a connection to a wider pitch or to reroute a connection to a different connection. Multiple chiplets working together in a single IC may be referred to as a multi-chip module (MCM), hybrid IC, 2.5D IC, standard package, or an advanced package.

On-package integration of chiplets enables a fast and cost-effective way to provide bespoke solutions. For example, different usages may need different acceleration capability but with the same cores, memory, and I/O. It also allows the co-packaging of dies where the optimal process node choice is made based on the functionality. For example, memory, logic, analog, and co-packaged optics each needs a different process technology which can be packaged with chiplets. Since package traces are short and offers dense routing, applications requiring high bandwidth such as memory access (e.g., High Bandwidth Memory), are implemented as on-package integration.

As depicted in FIG. 1, system 100 includes one or more processors 102 and one or more memory 106 coupled to a controller hub 104. A processor 102 may include any processing element, such as a microprocessor, a host processor, an embedded processor, a co-processor, or other processor. Each processor 102 is coupled to controller hub 104 through a link 120, such as a front-side bus (FSB), for example. In one embodiment, the link 120 is a serial point-to-point interconnect as described below. In another embodiment, link 120 includes a serial, differential interconnect architecture that is compliant with different interconnect standards. Interconnect protocols and features discussed below may be utilized to implement the links 120 coupling the set of components introduced here in FIG. 1.

Memory 106 includes any memory device, such as random access memory (RAM), non-volatile (NV) memory, or other memory accessible by devices in system 100. Memory 106 is coupled to controller hub 104 through a link 120, such as a memory interface, for example. Examples of a memory interface include a double-data rate (DDR) memory interface, a dual-channel DDR memory interface, and a dynamic RAM (DRAM) memory interface.

In one embodiment, controller hub 104 may be implemented as a root hub, root complex, or root controller in a Peripheral Component Interconnect Express (PCI Express® or PCIe®) and Compute Express Link™ (CXL™) interconnection hierarchy, or other industry standards. Examples of controller hub 104 include a chipset, a memory controller hub (MCH), a northbridge, an interconnect controller hub (ICH), a southbridge, and a root controller/hub. Often the term chipset refers to two physically separate controller hubs, e.g., a memory controller hub (MCH) coupled to an interconnect controller hub (ICH). Note that current systems often include the MCH integrated with processor 102, while controller hub 104 is to communicate with input/output (I/O) devices, in a similar manner as described below. In some embodiments, peer-to-peer routing is optionally supported through a root complex implemented by the controller hub 104.

Although not shown, controller hub 104 may be coupled to off-package devices via a switch or bridge through a serial link. I/O modules, also referred to as interfaces or ports, may implement a layered protocol stack to provide communication between controller hub 104 and one or more I/O devices via the switch. The switch/bridge may route packets or messages from an I/O device upstream towards a root complex of the controller hub 104 and downstream towards the I/O device. The switch may comprise a logical assembly of multiple virtual PCI-to-PCI bridge devices. An I/O device includes any internal or external device or component to be coupled to an electronic system, such as a Network Interface Controller (NIC), an add-in card, an audio processor, a network processor, a hard-drive, a storage device, a CD/DVD ROM, a monitor, a printer, a mouse, a keyboard, a router, a portable storage device, a Firewire device, a Universal Serial Bus (USB) device, a scanner, and other I/O devices. Often in the PCIe vernacular, such as device, is referred to as an endpoint. An I/O device may include a PCIe to PCI/PCI-X bridge to support legacy or other version PCI devices. Endpoint devices in PCIe are often classified as legacy, PCIe, or root complex integrated endpoints.

The system 100 may further include one or more accelerators 108. An accelerator is a separate architectural substructure that is architected using a different set of objectives than the base processor, where these objectives are derived from the needs of a special class of applications. Examples of accelerators include a graphics accelerator to enhance graphics rendering capability, a cryptographic accelerator to help with encryption or decryption, a web accelerator to improve web applications, a hypertext preprocessor (PHP) accelerator to assist in web development, and so forth.

Accelerators 108 are also coupled to controller hub 104 through links 120, such as a serial link, for example. In one embodiment, an accelerator 108 is a graphics accelerator coupled to an MCH, which is coupled to an ICH. The switch, and accordingly an I/O device, is then coupled to the ICH. The I/O modules may implement a layered protocol stack to communicate between the graphics accelerator and controller hub 104. Similar to the MCH discussion above, a graphics controller or the graphics accelerator itself may be integrated in a processor 102. Further, one or more links 120 of the system 100 can include one or more extension devices, such as retimers, repeaters, and so forth.

The system 100 may include other semiconductor dies to implement various compute or communications functions, such as a radio-frequency circuit 110, a modem 112, an optical device 114, an analog device 116, and so forth. Embodiments are not limited in the type or number of semiconductor dies implemented for the system 100.

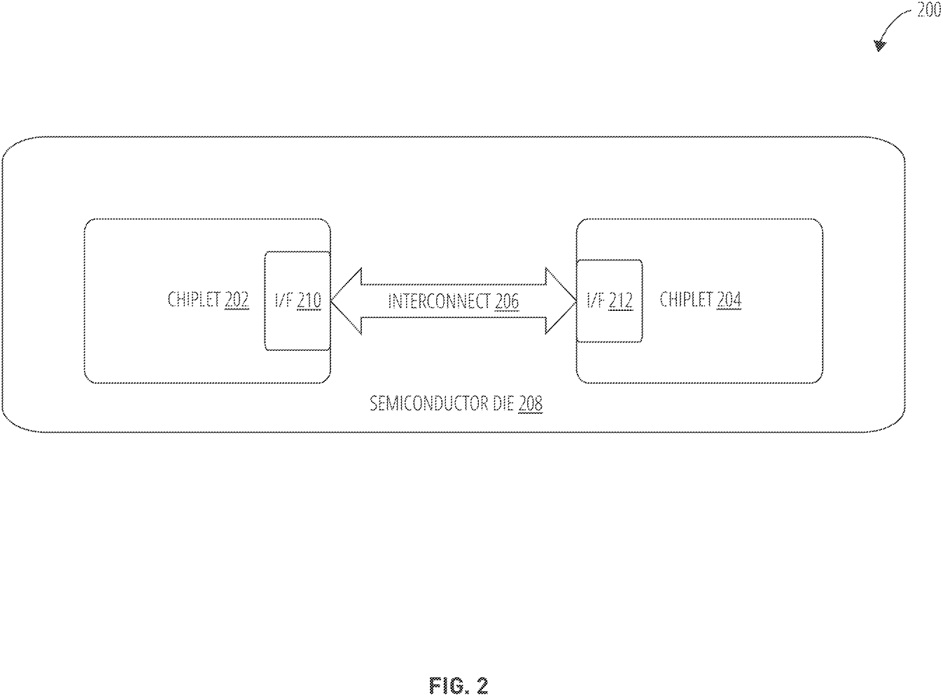

FIG. 2 illustrates a system 200. System 200 isolates a pair of chiplets that may be implemented by the system 100. System 200 may comprise a chiplet 202 and a chiplet 204 integrated on a single semiconductor die 208. The chiplet 202 may exchange signals with the chiplet 204 over an interconnect 206. The chiplet 202 and the chiplet 204 may implement interface 210 and interface 212, respectively. In one embodiment the chiplets 202, 204, the interfaces 210, 212, and/or the interconnect 206 may be UCIe-compliant devices.

UCIe is an open industry standard interconnect offering high-bandwidth, low-latency, power-efficient, and cost-effective on-package connectivity between chiplets. The UCIe Specification defines a ubiquitous interconnect at the package level and covers the die-to-die (D2D) input/output (I/O) physical layer, D2D protocols, and software stack which leverage the well-established Peripheral Component Interconnect Express (PCI Express® or PCIe®) and Compute Express Link™ (CXL™) industry standards.

The UCIe Specification details the complete standardized D2D interconnect with physical layer, protocol stack, software model, and compliance testing that will enable end users to easily mix and match chiplet components from a multi-vendor ecosystem for System-on-Chip (SoC) construction, including customized SoC. The physical layer supports up to 32 GT/s with 16 to 64 lanes and uses a 256 byte Flow Control Unit (FCU) for data, similar to PCIe 6.0. The protocol layer is based on Compute Express Link with CXL.io (PCIe), CXL.mem and CXL.cache protocols. Various on-die interconnect technologies are defined, like organic substrate for a “standard” 2D package, or embedded silicon bridge (EMIB), silicon interposer, and fanout embedded bridge for “advanced” 2.5D/3D packages. Physical specifications are based on the Advanced Interface Bus (AIB) as defined by Intel Corporation, headquartered in Santa Clara, California.

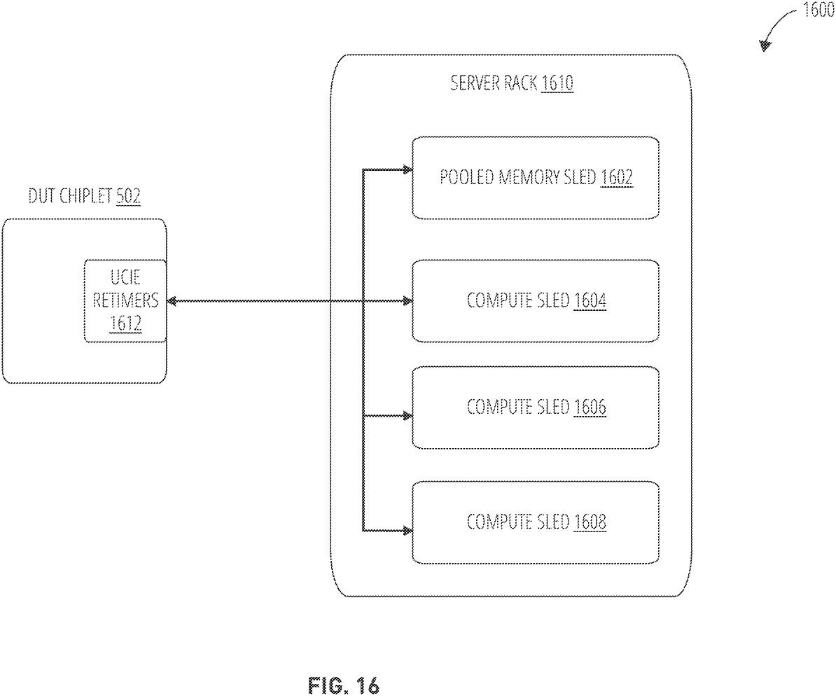

UCIe supports two broad usage models. The first is package level integration to deliver power-efficient and cost-effective performance, as shown by system 100. Components attached at the board level such as memory, accelerators, networking devices, modem, etc. can be integrated at the package level with applicability from hand-held to high-end servers with dies from multiple sources connected through different packaging options even on the same package. The second usage is to provide off-package connectivity using different type of media (e.g., optical, electrical cable, mmWave) using UCIe retimers to transport the underlying protocols (e.g., PCIe, CXL) at the rack or even the pod level for enabling resource pooling, resource sharing, and even message passing using load-store semantics beyond the node level to the rack/ pod level to derive better power-efficient and cost-effective performance at the edge and data centers. An architecture for the second usage is described with reference to system 1600 as shown in FIG. 16.

UCIe supports different data rates, widths, bump-pitches, and channel reach to ensure the widest interoperability feasible. It defines a sideband interface for ease of design and validation. The unit of construction of the interconnect is a cluster which comprises of N single-ended, unidirectional, full-duplex data lanes (where N= 16 for standard package and 64 for advanced package), one single-ended lane for valid, one lane for tracking, a differential forwarded clock per direction, and 2 lanes per direction for sideband (e.g., single-ended, one 1000 MHz clock and one data). The advanced package supports spare lanes to handle faulty lanes (e.g., including clock, valid, sideband, etc) where as the standard package supports width degradation to handle failures. Multiple clusters can be aggregated to deliver more performance per link.

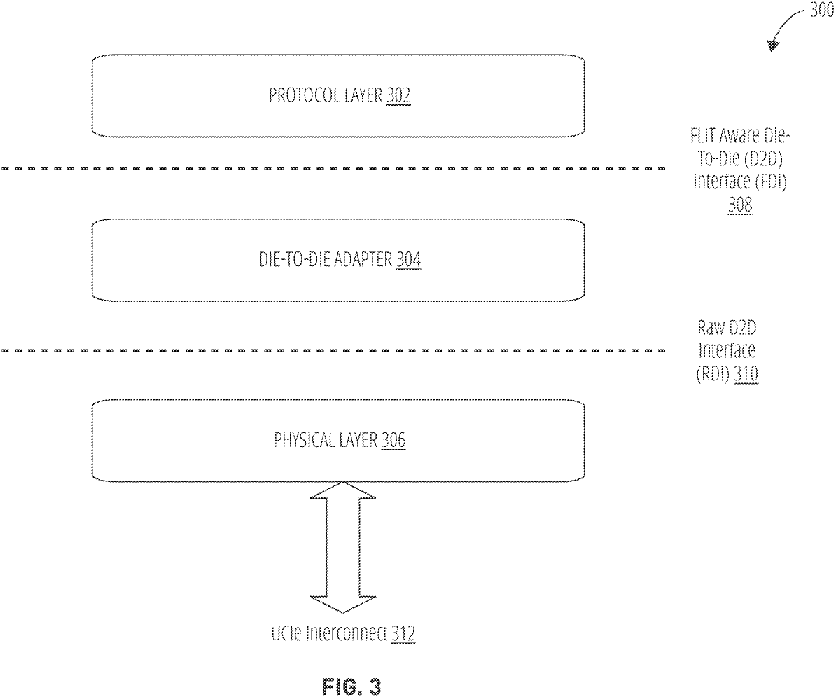

FIG. 3 illustrates an interconnect stack 300. UCIe is a layered protocol. Interconnect stack 300 may comprise a protocol layer 302, a die-to-die adapter 304, and a physical layer 306.

The physical layer 306 may be coupled to a UCIe interconnect 312, such as the interconnect 206 described with reference to FIG. 2. The physical layer 306 is responsible for the electrical signaling, clocking, link training, sideband, and other physical layer operations. Information may be passed between the physical layer 306 and the die-to-die adapter 304 over a raw D2D interface (RDI) 310.

The die-to-die adapter 304 provides link state management and parameter negotiation for the chiplets, such as the chiplets 202, 204, for example. It optionally guarantees reliable delivery of data through its cyclic redundancy check (CRC) and link level retry mechanism. When multiple protocols are supported, it defines the underlying arbitration mechanism. A 256-byte flow control unit (FCU) level interface transfer (FLIT) defines the underlying transfer mechanism when the adapter is responsible for reliable transfer. Information may be passed between the die-to-die adapter 304 and the protocol layer 302 over a FLIT aware D2D interface (FDI) 308.

UCIe maps PCIe and CXL protocols natively as those are widely deployed at the board level across all segments of compute. This is done to ensure seamless interoperability by leveraging the existing ecosystem. With PCIe and CXL, SoC construction, link management, and security solutions that are already deployed can be leveraged to UCIe. The usage models addressed are also comprehensive: data transfer using direct memory access, software discovery, error handling, etc., are addressed with PCIe/ CXL.io; the memory use cases are handled through CXL.Mem; and caching requirements for applications such as accelerators are addressed with CXL.cache. UCIe also defines a “streaming protocol” which can be used to map any other protocol. Further, the UCIe consortium can innovate on protocols in the future optimized for chiplets as usage models evolve in the future.

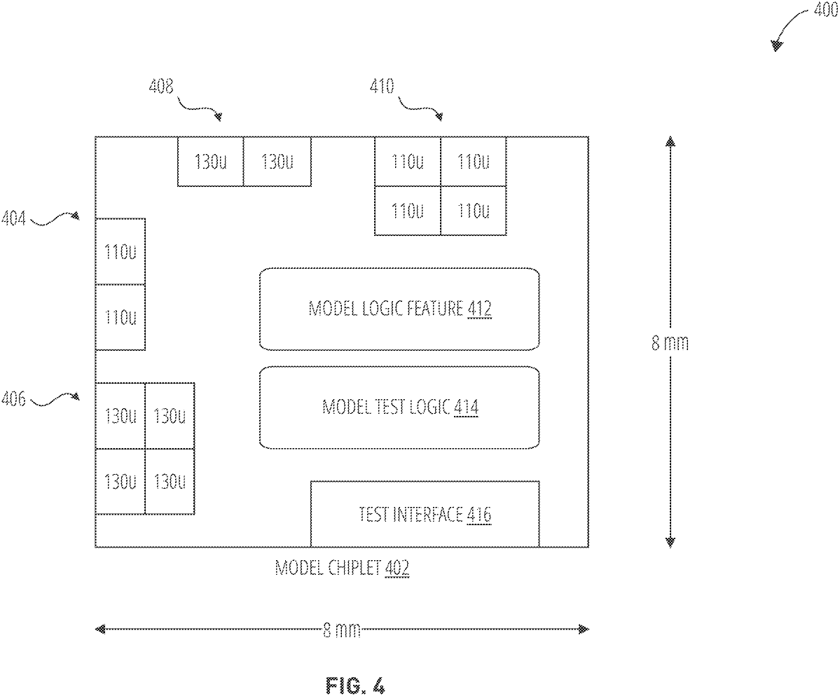

FIG. 4 illustrates a top view of a model chiplet 402 suitable for use in semiconductor testing. The model chiplet 402 implements a superset of features supported by the UCIe Specification, as well as logic for testing another chiplet, such as a DUT chiplet. The model chiplet 402 is referred to as a known good model (KGM) as it has been previously tested for compliance with the UCIe Specification. Since it is a KGM, the model chiplet 402 can be used as a reference to test an unknown good model (UGM), such as an untested or modified DUT chiplet, for a given set of features supported by the UCIe Specification.

As depicted in FIG. 4, the model chiplet 402 may include various physical layer (PHY) PHY modules 404. The model chiplet 402 may instantiate all possible configurations of PHY modules 404 that may be needed to test a DUT chiplet. PHY modules 404 may have a configuration of two single-stack modules at 110 microns, two single-stack modules at 130 microns, four double-stacked modules at 110 microns, and four double-stacked modules at 130 microns. In one embodiment, the model chiplet 402 may have X and Y dimensions of 8 millimeters (mm) x 8 mm, although other X and Y dimensions may be used as well. Embodiments are not limited in this context.

The model chiplet 402 may also have a set of model logic features 412. In one embodiment, the model logic features 412 may comprise a complete set of UCIe features as defined by the UCIe Specification. Other semiconductor specifications may be used as well. Embodiments are not limited in this context.

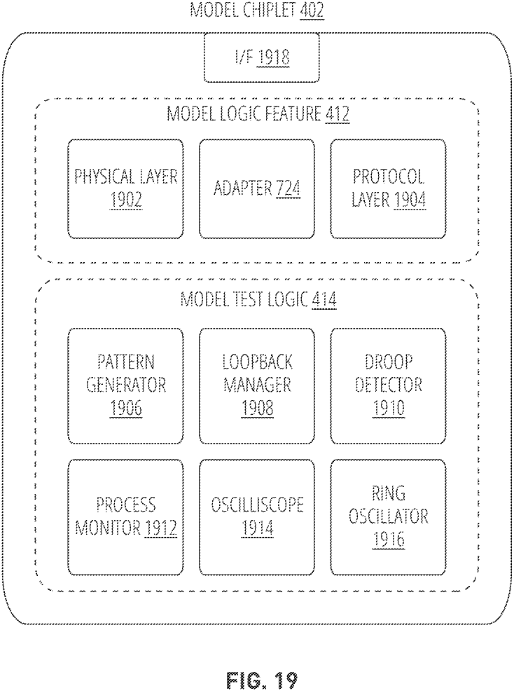

The model chiplet may also have model test logic 414. The model test logic 414 may assist in testing operations of another chiplet, such as a DUT chiplet, for example. The model test logic 414 may be described in more detail with reference to FIG. 19.

The model chiplet 402 may also have a test interface 416. The test interface 416 is a port to allow communication with external test equipment, or in some cases, with a DUT chiplet (e.g., for testing commands or other sideband communications). In one embodiment, the test interface 416 may be implemented as a serializer/deserializer (SerDes or SERDES) interface., such as PCIe, Ethernet, or some other high-bandwidth interface.

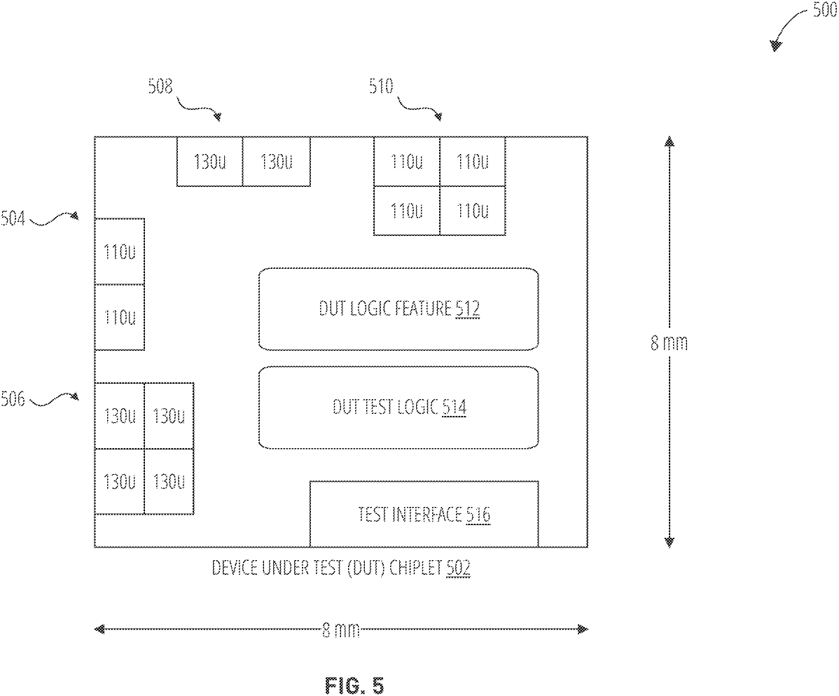

FIG. 5 illustrates a top view of a DUT chiplet 502 suitable for use in semiconductor testing. The DUT chiplet 502 implements a set of features supported by the UCIe Specification, as well as logic for conducting testing operations in cooperation with another chiplet, such as the model chiplet 402. The DUT chiplet 502 is referred to as a UGM as it has not been previously tested for compliance with the UCIe Specification. Since it is a UGM, the DUT chiplet 502 can be tested against a reference that is a KGM, such as a tested model chiplet 402, for a given set of features supported by the UCIe Specification. The differentials between the KGM and the UGM may provide information as to whether the UGM meets specifications defined by the UCIe Specification.

The DUT chiplet 502 may share some features in common with the model chiplet 402. As depicted in FIG. 5, the DUT chiplet 502 may include various PHY modules. Unlike the model chiplet 402 which instantiates all possible configurations of PHY modules 404 that may be needed to test a DUT chiplet, the DUT chiplet 502 typically instantiates a single configuration of PHY modules as designed by an original equipment manufacturer (OEM) of the DUT chiplet 502. As such, the DUT chiplet 502 may have PHY modules 510 with a configuration of two single-stack modules at 110 microns, PHY modules 508 with a configuration of two single-stack modules at 130 microns, PHY modules 510 with a configuration of four double-stacked modules at 110 microns, or PHY modules 506 with a configuration of four double-stacked modules at 130 microns. In one embodiment, the DUT chiplet 502 may have X and Y dimensions that match the model chiplet 402, such as 8 mm × 8 mm. In other embodiments, the DUT chiplet 502 may have X and Y dimensions that are different from the model chiplet 402. Embodiments are not limited in this context.

The DUT chiplet 502 may also have a set of DUT logic features 512. The set of DUT logic features 512 may match the set of model logic features 412, or comprise a subset of the model logic features 412. In one embodiment, the DUT logic features 512 may be implemented as UCIe features as defined by the UCIe Specification. Other semiconductor specifications may be used as well. Embodiments are not limited in this context.

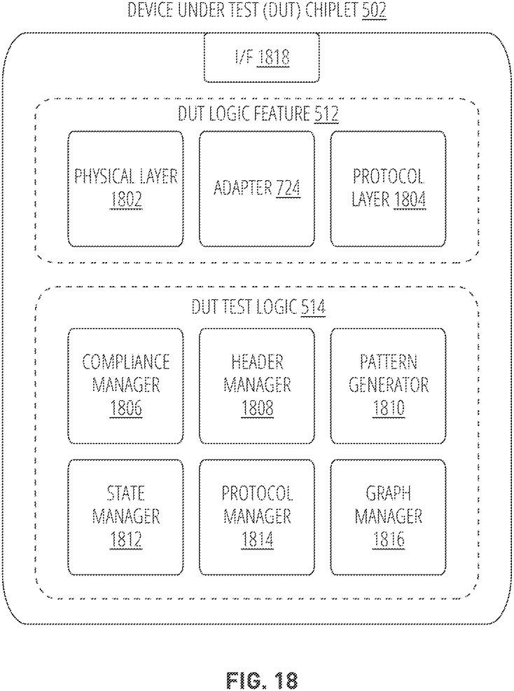

The DUT chiplet 502 may also have DUT test logic 514. The DUT test logic 514 may compliment the model test logic 414 to facilitate testing operations as directed by another chiplet, such as the model chiplet 402, for example. The DUT test logic 514 may be described in more detail with reference to FIG. 18.

The DUT chiplet 502 may optionally have a test interface 516. The test interface 516 is a port to allow communication with external test equipment, or in some cases, with the model chiplet 402 (e.g., for testing commands or other sideband communications). In one embodiment, the test interface 516 may be implemented as a SERDES interface., such as PCIe, Ethernet, or some other high-bandwidth interface.

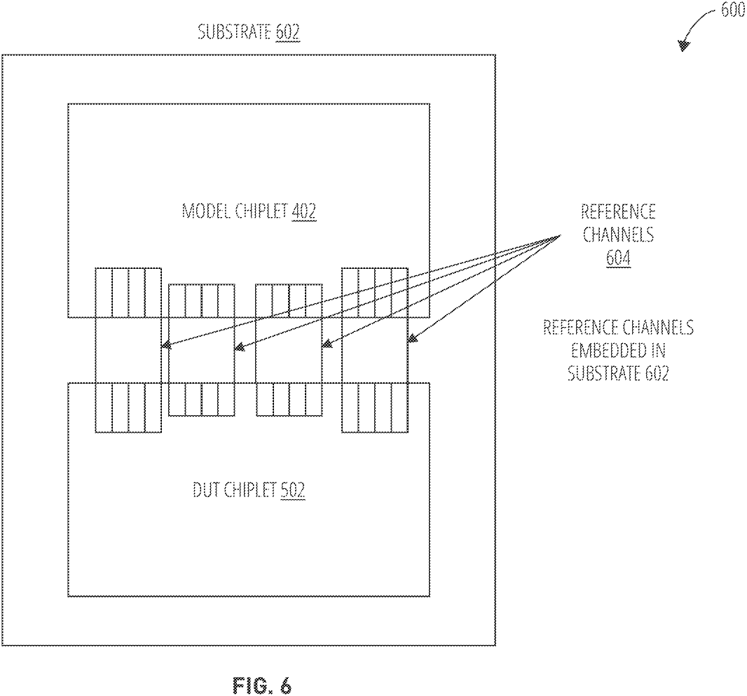

FIG. 6 illustrates a test package 600. The test package 600 includes the model chiplet 402 and the DUT chiplet 502 assembled on a substrate 602. The model chiplet 402 and the DUT chiplet 502 may communicate over a set of reference channels 604. In one embodiment, the reference channels 604 are embedded in the substrate 602. The reference channels 604 may be implemented as wire bonds, traces, a silicon bridge, interposer, and other communications media.

The test package 600 may have different physical configurations for semiconductor testing, with the different physical configurations defined using different reference packages, such as a strict reference package and DUT form factor, a flexible reference package and DUT form factor, and a custom reference package for an OEM.

The strict reference package may have a strict form factors for the test package 600, model chiplet 402 and DUT chiplet 502. This option and concept can apply to both standard packages (e.g., standard laminate packages) as well as advanced packages (e.g., EMIB, CoWoS, Fan-Out technologies (FO), Silicon interposers - both active and passive, and so forth). The test package 600 would have specified dimensions as well as package-side bump locations for the model chiplet 402 and DUT chiplet 502 to be assembled on as well as embedded interconnect wiring/routing within the package layers to allow communication between the model chiplet 402 and DUT chiplet 502 through their respective UCIe physical layers (PHYs) once assembled. The reference channels 604 comprising the interconnect wiring/routing are carefully designed to meet the UCIe interconnect channel specifications at the specification limits so as to serve as a reference for the model chiplet 402 and the DUT chiplet 502 that will communicate over the reference channels 604.

In strict reference package, the model chiplet 402 would have specified X and Y dimensions and an exact bumpout definition. The bumpout definition would contain specific locations for both the UCIe IPs and associated bumpouts in addition to bumpout for the entire remainder of the die so as to allow it to be assembled. Similarly, the DUT chiplet 502 would have specified X and Y dimensions and an exact bumpout definition. The bumpout definition would contain specific locations for both the UCIe IPs and associated bumpouts in addition to bumpout for the entire remainder of the die so as to allow it to be assembled. The specification for the DUT chiplet 502 could be the same as the model chiplet 402 or they can be different. In the case where they are exactly the same, this configuration would allow multiple model chiplets 402 in a test package 600 to test the model chiplets 402. This will allow for characterization of the embedded reference channels 604 in the test package 600.

The strict reference package has advantages of the most controlled environment with the least number of variables and fixed or known reference channels 604. However, it offers the least amount of flexibility and requires conformance to exact and specific form factors for size and bumpout locations.

The flexible (or semi-strict) reference package defines strict form factors for the model chiplet 402 and the DUT chiplet 502. While the model chiplet 402 is mounted in a pre-defined location, the DUT chiplet 502 may be mounted at a custom location that is unique for each implementation. The model chiplet 402 may have the same description as the strict reference package. However, the DUT chiplet 502 is not specified in terms of X and Y dimensions nor bumpout of the entire die. Therefore, only the logical functions and the UCIe IP portions of the DUT chiplet 502 would need to meet a specific definition.

The flexible reference package still offers a reasonably well-controlled environment with a lower number of variables. However, this option may increase time and costs since it requires essentially a new package tape-out. Also, the reference channels 604 will vary since routing will be re-done for each test package 600.

In the custom reference package, the model chiplet 402 is integrated into an OEM system on a chip (SOC) or test package 600 to directly test against one or more DUT chiplets 502. In this option, the test package 600 can be unique for each OEM and each of their products to allow for certification at the product level vs the UCIe IP level (as in options 1 and 2 above). The model chiplet 402 may have a definition that is the same or similar to options 1 and 2 as described above. The DUT chiplet 502, however, can be unique for each OEM and each of their products.

The custom reference package offers the most flexibility for OEMs and demonstration of compliance in “real” environments. A custom SOC or package may contain an actual OEM product with working reference channels 604 designed to operate for an OEM customer product. However, the custom reference package offers the least controlled environment, and it also may increases time and costs since it requires a new package tape-out.

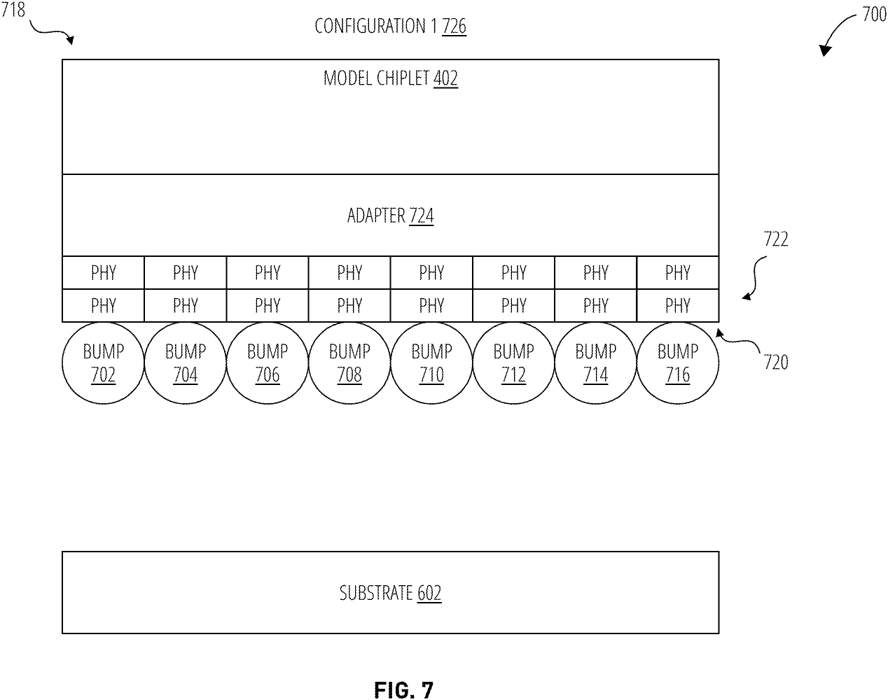

FIG. 7 illustrates a side view of a semiconductor die 700. The semiconductor die 700 may be an example of an instantiation of the model chiplet 402. In this instantiation the model chiplet 402 may have dimensions of 8 mm × 8 mm or 6 mm × 6 mm, for example.

The model chiplet 402 may have multiple implementation options or configurations. A first configuration may be implemented as a stacked configuration of the UCIe PHY IP on a die, where each UCIe PHY IP comprises a transmit array and a receive array. A second configuration may be implemented as an unstacked configuration of the UCIe PHY IP on a die. A third configuration may be implemented with the first and second configurations on a single die. The third configuration may allow testing a DUT chiplet 502 with either configuration without having to instantiate the first and second configurations. This may allow for smaller physical dimensions for the model chiplet 402. Each configuration may comprise a UCIe adapter with supporting logic, along with a test interface such as test interface 416 to allow for communication to external testing equipment.

The semiconductor die 700 shows a configuration 1 726 for the model chiplet 402. As depicted in FIG. 7, the model chiplet 402 may have a top side 718 and a bottom side 720. The bottom side 720 may have a set of bumpouts represented as bump 702 to bump 716. The bumps 702-716 may be assembled to a substrate 602 of a test package 600.

The model chiplet 402 may implement a set of eight double-stacked PHY 722 each corresponding to a bump 702 to bump 716. Each PHY may be a UCIe PHY-s module that implements a UCIe physical layer 306 of the interconnect stack 300. The eight double-stacked PHY 722 may cover both stacked and unstacked configurations for a DUT chiplet 502.

The model chiplet 402 may also have an adapter 724. In one embodiment, the adapter 724 may comprise a UCIe adapter that conforms to the UCIe die-to-die adapter 304 of the interconnect stack 300.

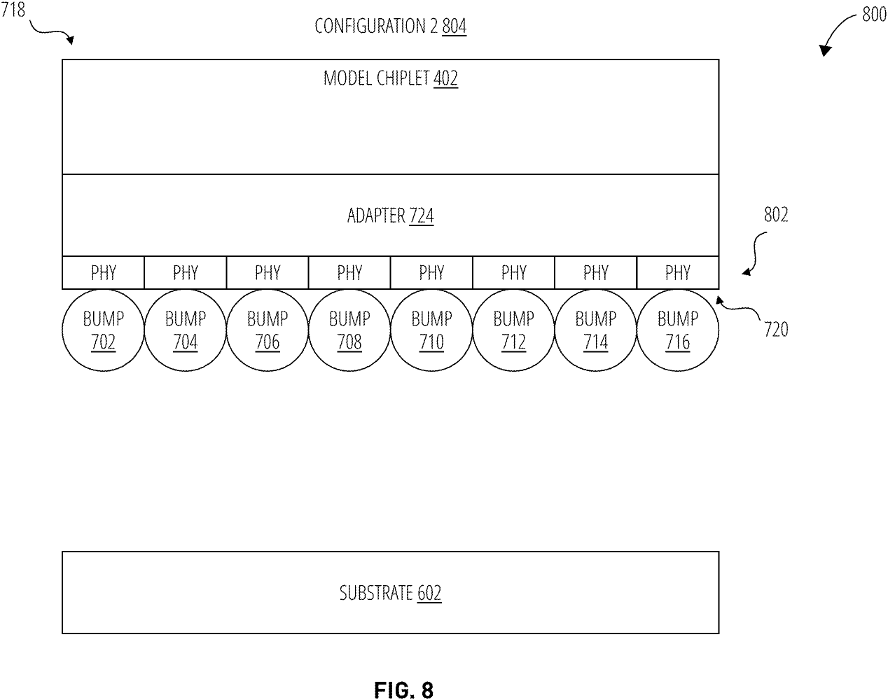

FIG. 8 illustrates a side view of a semiconductor die 800. The semiconductor die 800 may be an example of an instantiation of the model chiplet 402. In this instantiation the model chiplet 402 may have dimensions of 8 mm × 8 mm or 6 mm × 6 mm, for example.

The semiconductor die 800 may be an example for the model chiplet 402. More particularly, the semiconductor die 800 shows a configuration 2 804 for the model chiplet 402. As depicted in FIG. 8, the model chiplet 402 may have a top side 718 and a bottom side 720. The bottom side 720 may have a set of bumpouts represented as bump 702 to bump 716. The bumps 702-716 may be assembled to a substrate 602 of a test package 600.

The model chiplet 402 may implement a set of eight single-stack PHY 802 each corresponding to a bump 702 to bump 716. Each PHY may be a UCIe PHY-s module that implements a UCIe physical layer 306 of the interconnect stack 300. The eight single-stack PHY 802 may cover unstacked configurations for a DUT chiplet 502.

The model chiplet 402 may also have an adapter 724. In one embodiment, the adapter 724 may comprise a UCIe adapter that conforms to the UCIe die-to-die adapter 304 of the interconnect stack 300.

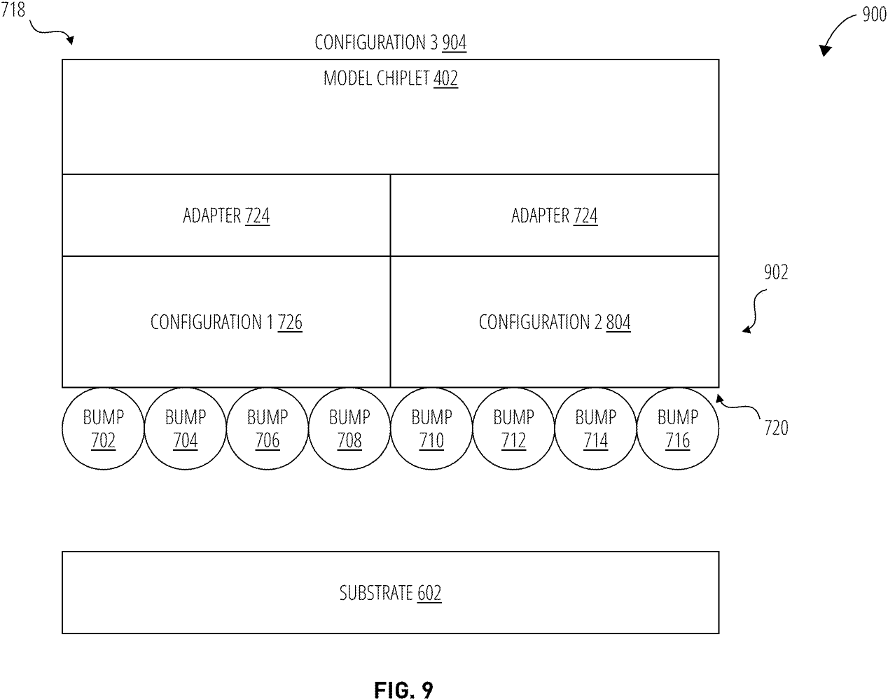

FIG. 9 illustrates a side view of a semiconductor die 900. The semiconductor die 900 may be an example of an instantiation of the model chiplet 402. In this instantiation the model chiplet 402 may have dimensions of 11 mm × 11 mm, for example.

The semiconductor die 900 may be an example for the model chiplet 402. More particularly, the semiconductor die 900 shows a configuration 3 904 that implements both configuration 1 726 and configuration 2 804 for the model chiplet 402 on a single die.

As depicted in FIG. 9, the model chiplet 402 may have a top side 718 and a bottom side 720. The bottom side 720 may have a set of bumpouts represented as bump 702 to bump 716. FIG. 9 illustrates only eight bumps for purposes of clarity. The actual number of bumps may match a corresponding number of PHY configuration 902 in a particular stacked or unstacked configuration, which in this example is a set of 16 PHYS, with eight stacked in four stacks and eight unstacked, which would therefore need a set of 12 bumps. The bumps 702-716 may be assembled to a substrate 602 of a test package 600.

The model chiplet 402 may implement a set of eight single-stack PHY 802 and a subset of four double-stacked PHY 722 with each stack comprising two PHYS. Each of the eight single-stack PHY 802 and the four double-stacked PHY 722 may correspond to a bump such as those depicted as bump 702 to bump 716. Each PHY may be a UCIe PHY-s module that implements a UCIe physical layer 306 of the interconnect stack 300. The four double-stacked PHY 722 and the eight single-stack PHY 802 may cover both stacked and unstacked configurations for a DUT chiplet 502.

The model chiplet 402 may also have an adapter 724. In one embodiment, the adapter 724 may comprise a UCIe adapter that conforms to the UCIe die-to-die adapter 304 of the interconnect stack 300.

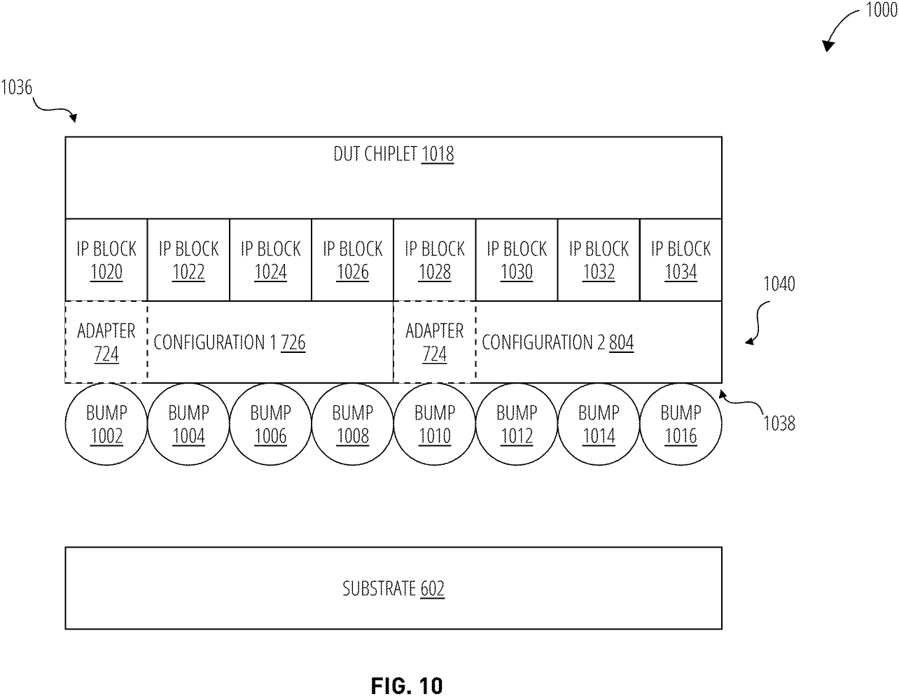

FIG. 10 illustrates a side view of a semiconductor die 1000. The semiconductor die 1000 may be an example of an instantiation of the DUT chiplet 502. In this instantiation the DUT chiplet 502 may have dimensions suitable for the different dimensions implemented by the different configurations of the model chiplet 402. In addition, the DUT chiplet 502 may have side bumps on package (not shown), referred to as package-side bump (PSB) shadows, for the UCIe components and/or the entire DUT chiplet 502.

As depicted in FIG. 10, the DUT chiplet 502 may have a top side 1036 and a bottom side 1038. The bottom side 1038 may have a set of bumpouts represented as bump 1002 to bump 1016. FIG. 10 illustrates only eight bumps for purposes of clarity. The actual number of bumps may match a corresponding number of PHYS in a particular stacked or unstacked configuration implemented for a PHY configuration 1040. The bumps 1002-1016 may be assembled to the substrate 602 of the test package 600.

The DUT chiplet 502 may have a set of intellectual property (IP) blocks 1020-1034. The IP blocks 1022-1034 may represent any custom logic for the DUT chiplet 502, such as a specialized function for a prototype or commercial product. Some of the IP blocks may implement test logic for the DUT chiplet 502, as described further below.

The DUT chiplet 502 may also implement a PHY configuration 1040. The PHY configuration 1040 may comprise a set of PHYS, such as double-stacked PHY 722 or single-stack PHY 802, that are the same or similar to the configuration 1 726 or the configuration 2 804 of the model chiplet 402, depending on a given implementation for an OEM. For instance, the PHY configuration 1040 may comprise a set of eight double-stacked PHY 722, a set of eight single-stack PHY 802, or a subset of four double-stacked PHY 722 with each stack comprising two PHYS. Each of the stacked or unstacked PHYS may correspond to a bump such as those depicted as bump 1002 to bump 1016. Each PHY may be a UCIe PHY-s module that implements a UCIe physical layer 306 of the interconnect stack 300.

The DUT chiplet 502 may also have an adapter 724 as part of the PHY configuration 1040. In one embodiment, the adapter 724 may comprise a UCIe adapter that conforms to the UCIe die-to-die adapter 304 of the interconnect stack 300.

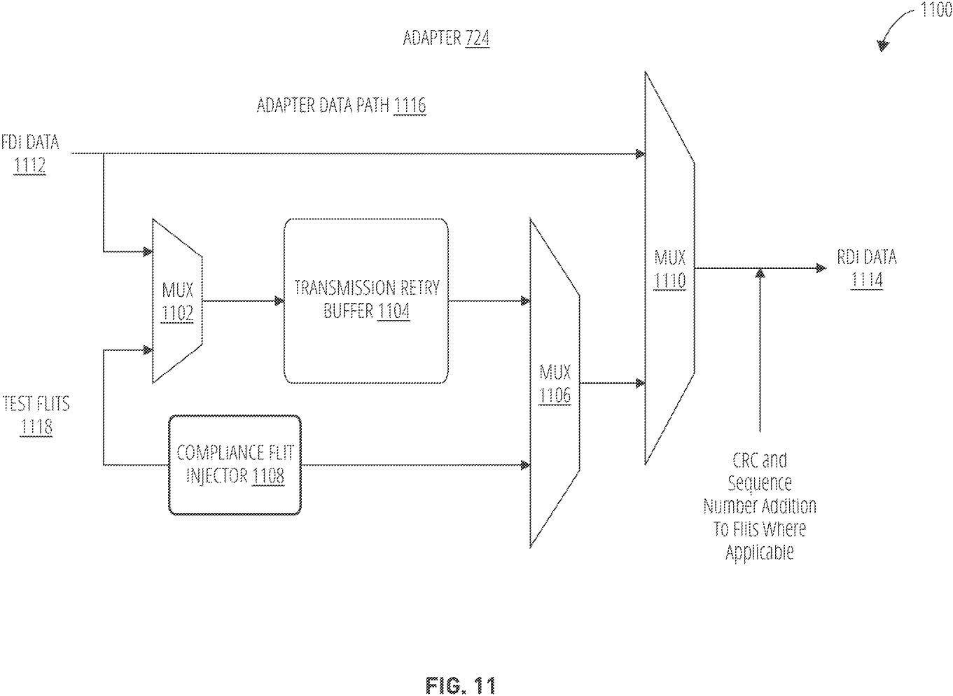

FIG. 11 illustrates an example of the adapter 724 implemented by the model chiplet 402 and/or the DUT chiplet 502. In one embodiment, the adapter 724 may be standard UCIe adapter similar to the die-to-die adapter 304 of the interconnect stack 300. In addition, the adapter 724 may be modified with logic to assist in testing the DUT chiplet 502.

As depicted in FIG. 11, the the adapter 724 may have an adapter data path 1116 that receives as input FDI data 1112 from the FDI 308 and routes the FDI data 1112 to a multiplexer 1102 and a multiplexer 1110.

In addition, the adapter 724 may implement a compliance FLIT injector 1108 that generates test information or test patterns for testing the DUT chiplet 502. The compliance FLIT injector 1108 may generate flow control unit (FCU) level interface transfer (FLIT) data. FLITs are the basic unit of data transfer in UCIe, and comprise a fixed number of bytes (e.g., typically 64 or 128) that are transferred between chiplets. The FLIT also includes metadata such as control information, error correction codes, and flow control signals. A flow control unit (FCU) is responsible for managing the transfer of FLITs between chiplets, including buffering, routing, and flow control. The FCU Level Interface Transfer refers to an interface between the FCUs of two chiplets, and the transfer of FLITs between them.

The compliance FLIT injector 1108 may control FLIT generation to assist in testing the DUT chiplet 502. The compliance FLIT injector 1108 may generate test information in the form of test FLITs 1118, and output the test FLITs 1118 to the multiplexer 1102 and a multiplexer 1106. The test FLITs 1118 may comprise standard FLITs or modified FLITs.

The compliance FLIT injector 1108 may generate the standard FLITs or modified FLITs in standard patterns or test patterns. In various embodiments, the compliance FLIT injector 1108 may generate cyclic redundancy check (CRC) error injection patterns to test the different retry scenarios in a receive adapter of the DUT chiplet 502. The compliance FLIT injector 1108 may force negative acknowledgement or not acknowledged (NAKs) signals in different injection patterns to test the different retry functionality in a transmit adapter of the DUT chiplet 502. The compliance FLIT injector 1108 may delay acknowledgement (ACK) and/or NAK patterns in order to stress retry buffer full conditions and other conditions. The compliance FLIT injector 1108 may check injected patterns from the DUT chiplet 502.

An example set of register bits to test adapter capabilities for UCIe compliance is given in TABLE 1, as follows:

TABLE 1

| BIT | DESCRIPTION |
|---|---|
| 0 | Compliance_mode_enable: Must be programmed to 1b before Starting Link Training. |
| 2:1 | Flit_type_injection: |
| | 00b : NOP only |
| | 01b : non-NOP only |
| | 10b : alternating NOP and non-NOP |
| | 11b : Reserved |
| 4:3 | Byte_injection_pattern: |
| | 00b : All 0 bytes |
| | 01b : Clock pattern (alternating 1 s and 0 s) |
| | 10b : 4 byte pattern determined by bits 63:32 |
| | 11b : reserved |
| 8:5 | Offset: number of clock cycles offset between pattern injection on adjacent bytes |
| 9 | Injection Start: Software writes 1b to this bit to trigger the beginning of test. Hardware clears this bit when injection has begun. |
| 10 | Trigger for state transition: Software writes 1b to this bit to trigger a state transition on Adapter LSM. Hardware clears this bit once state transition has completed. |
| 11 | Trigger for RDI state transition. Software writes 1b to this bit to trigger a state transition on RDI. Hardware clears this bit once state transition has completed. |
| 15:12 | State transition encoding: |
| | 0000b : reserved |
| | 0001b : Active |
| | 0010b : Retrain |
| | 0011b : L1 |
| | 0100b : L2 |
| | 1000b : LinkReset |
| | 1001b : Disabled |
| | 1010b : LinkError |
| 31:16 | Reserved |
| 63:32 | Injection Pattern bytes for non-NOP Flits. |

The multiplexer 1102 may receive as input the FDI data 1112 and the test FLITs 1118. The multiplexer 1102 may output a signal to a transmission retry buffer 1104. The transmission retry buffer 1104 may output a signal to the multiplexer 1106. The multiplexer 1106 receives as input the output signals from the transmission retry buffer 1104 and the compliance FLIT injector 1108, and generates an output signal to the multiplexer 1110.

The multiplexer 1110 receives as input the FDI data 1112 and the output signal from the multiplexer 1106. The multiplexer 1110 may output RDI data 1114 to a PHY such as the physical layer 306 of the interconnect stack 300 for transport over a UCIe interconnect, such as the reference channels 604 and/or interconnect 206. The RDI data 1114 may include CRC and sequence numbers added to FLITs where applicable.

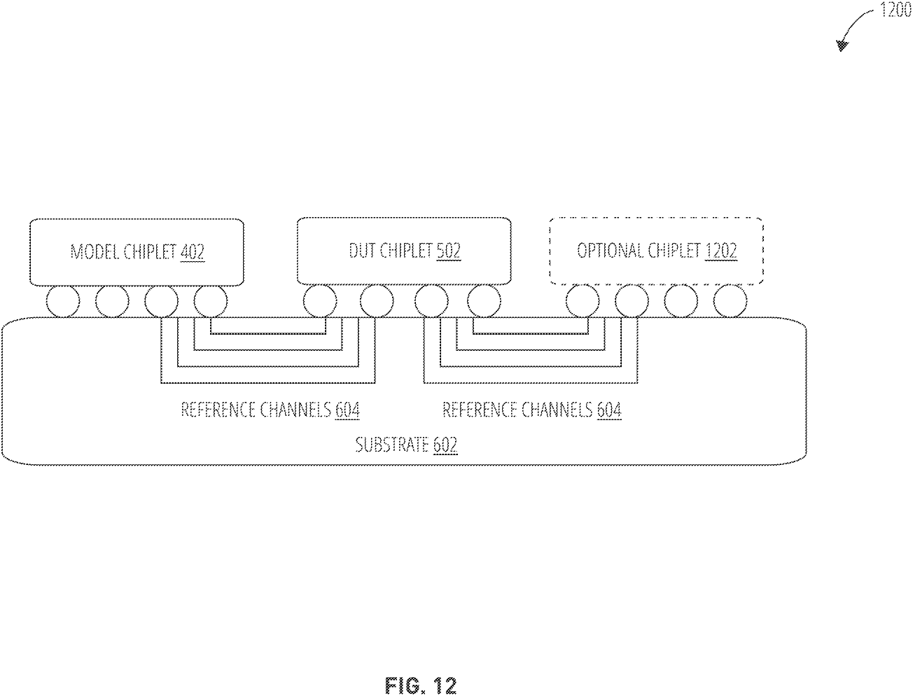

FIG. 12 illustrates a standard test package 1200. The UCIe Specification defines two types of packaging. The standard test package 1200 is an example of a standard package (2D) that is used for cost effective performance. There are multiple commercially available options, some of which are shown in the diagram. The UCIe Specification embraces all types of packaging choices in these categories.

In one embodiment, the test package 600 may be instantiated as a standard test package 1200. This allows the test package 600 to be tested as it would be deployed in commercially available options.

The standard test package 1200 may illustrate the model chiplet 402 and the DUT chiplet 502 assembled on the substrate 602. The substrate may have embedded a set of reference channels 604. The reference channels 604 may be conductive path between the model chiplet 402 and the DUT chiplet 502. The standard test package 1200 may optionally include an optional chiplet 1202. The optional chiplet 1202 may comprise another model chiplet 402 for model chiplet testing, another DUT chiplet 502 for parallel testing, or a chiplet that interoperates with the DUT chiplet 502 to enhance testing for the DUT chiplet 502. Embodiments are not limited in this context.

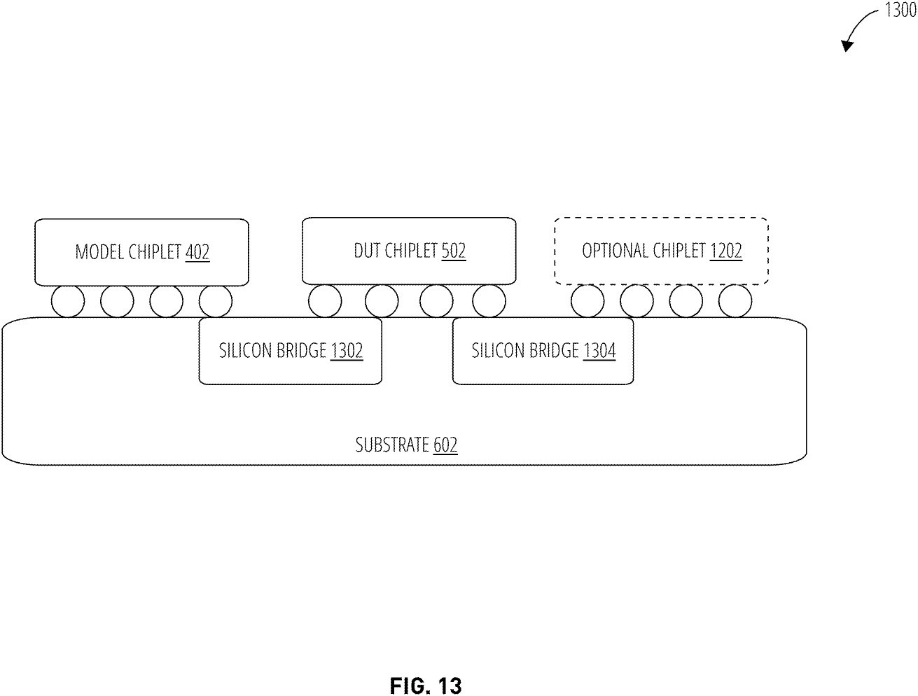

FIG. 13 illustrates an advanced test package 1300. As previously discussed, the UCIe Specification defines two types of packaging. The standard test package 1200 is an example of a standard package (2D) that is used for cost effective performance. The advanced test package 1300 is an example of a more advanced package that is used for power-efficient performance. There are multiple commercially available options for an advanced package, and the advanced test package 1300 is one commercially available option. The UCIe Specification embraces all types of packaging choices in these categories.

In one embodiment, the test package 600 may be instantiated as the advanced test package 1300. This allows the test package 600 to be tested as it would be deployed in commercially available options.

The advanced test package 1300 may illustrate the model chiplet 402 and the DUT chiplet 502 assembled on the substrate 602. Instead of the substrate 602 having an embedded set of reference channels 604, however, the substrate 602 may implement a silicon bridge 1302 and/or a silicon bridge 1304.

The silicon bridge 1302 and/or the silicon bridge 1304 may contain the reference channels 604 as a conductive path between the model chiplet 402 and the DUT chiplet 502. In general, a silicon bridge in a substrate refers to a structure in which a layer of silicon material is used to connect two or more isolated regions or components on a substrate. The silicon bridge is typically formed using semiconductor processing techniques such as photolithography, etching, and deposition. Silicon bridges 1302, 1304 can be used to create electrical connections between isolated components on a substrate, such as the model chiplet 402 and the DUT chiplet 502, which can be useful for integrating multiple functions or devices on a single chip. Silicon bridges can also be used to isolate or separate different regions on a substrate. For example, a silicon bridge might be used to create a barrier between different types of materials, such as a metal layer and a silicon layer, to prevent unwanted interactions or contamination.

The advanced test package 1300 may optionally include an optional chiplet 1202. The optional chiplet 1202 may comprise another model chiplet 402 for model chiplet testing, another DUT chiplet 502 for parallel testing, or a chiplet that interoperates with the DUT chiplet 502 to enhance testing for the DUT chiplet 502. Embodiments are not limited in this context.

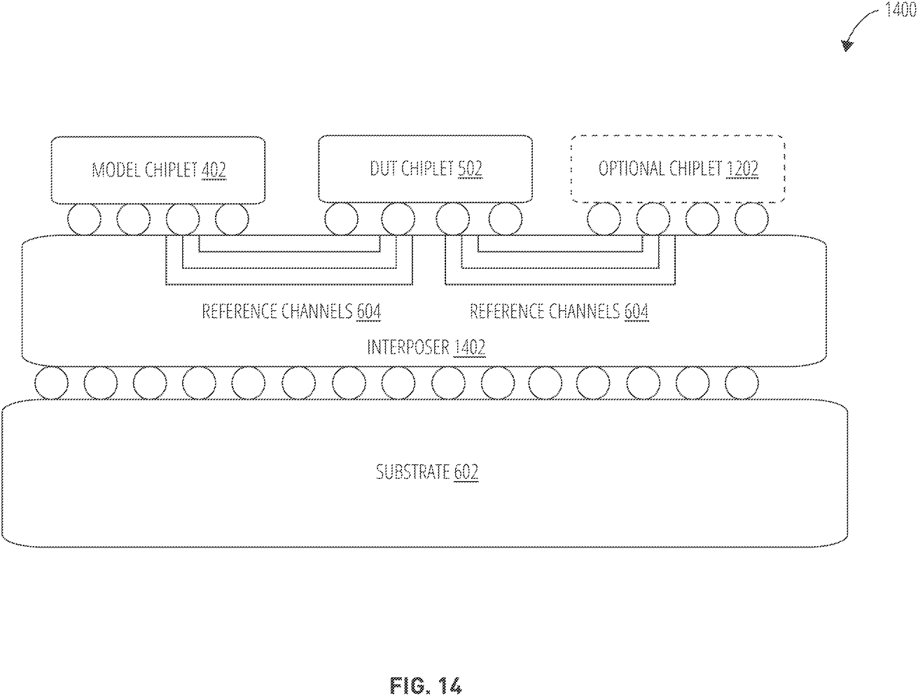

FIG. 14 illustrates an advanced test package 1400. The UCIe Specification defines two types of packaging. The advanced test package 1400 is an advanced package (2.5D) that is used for power-efficient performance. There are multiple commercially available options for the advanced package.

The advanced test package 1400 is another example of a more advanced package that is used for power-efficient performance. In one embodiment, the test package 600 may be instantiated as the advanced test package 1400. This allows the test package 600 to be tested as it would be deployed in commercially available options.

The advanced test package 1400 may illustrate the model chiplet 402 and the DUT chiplet 502 assembled on an interposer 1402. The interposer 1402 may have an embedded set of reference channels 604. The interposer 1402 may be assembled on the substrate 602.

The interposer 1402 is an electronic component that acts as an interface between a chip or integrated circuit and its package or substrate. An interposer provides a connection between the chip and the package by routing electrical signals between them. The interposer is typically a thin piece of material, such as silicon or organic substrate, that contains a network of electrical traces or vias. These traces are used to route signals between the chip and the package, and may also include power and ground connections. The interposer may be used in advanced packaging technologies such as 2.5D and 3D packaging, where multiple chips are stacked on top of each other to increase performance and reduce the overall size of the package. By using the interposer 1402, the chips can be connected to each other and to the package substrate 602 without the need for wire bonding or flip-chip packaging. The interposer may also enable heterogeneous integration, where chips with different technologies, such as CPUs and memory, can be integrated into a single package. This allows for improved performance, power efficiency, and reduced cost compared to traditional packaging technologies.

The advanced test package 1400 may optionally include an optional chiplet 1202. The optional chiplet 1202 may comprise another model chiplet 402 for model chiplet testing, another DUT chiplet 502 for parallel testing, or a chiplet that interoperates with the DUT chiplet 502 to enhance testing for the DUT chiplet 502. Embodiments are not limited in this context.

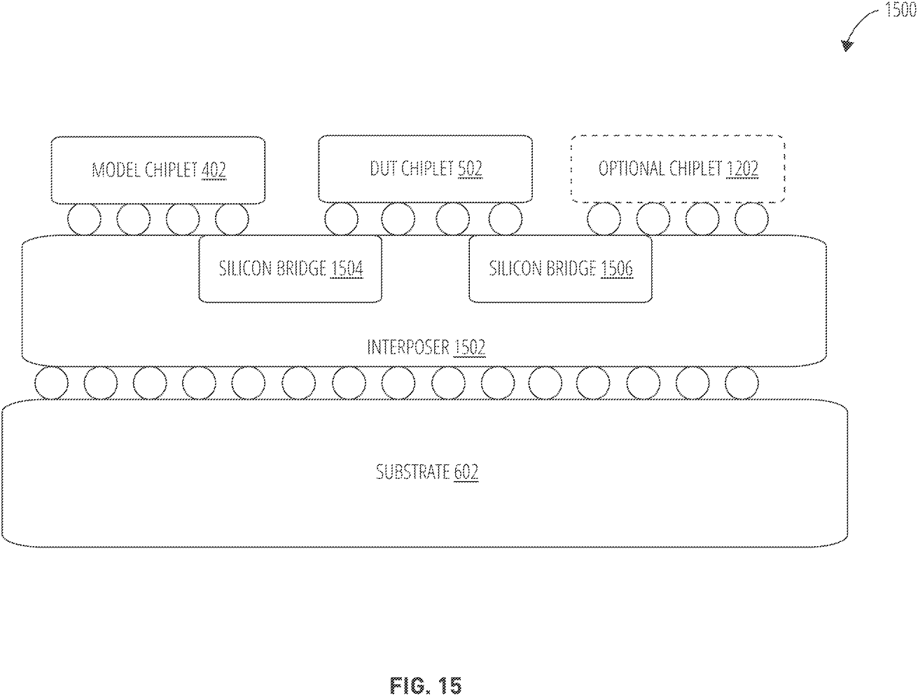

FIG. 15 illustrates an advanced test package 1500. The UCIe Specification defines two types of packaging. The advanced test package 1500 is an advanced package (2.5D or 3D) that is used for power-efficient performance. There are multiple commercially available options for the advanced package.

The advanced test package 1500 is yet another example of a more advanced package that is used for power-efficient performance. In one embodiment, the test package 600 may be instantiated as the advanced test package 1500. This allows the test package 600 to be tested as it would be deployed in commercially available options.

The advanced test package 1500 may illustrate the model chiplet 402 and the DUT chiplet 502 assembled on an interposer 1502. The interposer 1502 may embed a silicon bridge 1504 and/or a silicon bridge 1506 with reference channels 604. The silicon bridge 1504 and silicon bridge 1506 may be similar to the silicon bridge 1302 and silicon bridge 1304 as described with reference to FIG. 13. The interposer 1502 may be assembled on the substrate 602.

The advanced test package 1500 may optionally include an optional chiplet 1202. The optional chiplet 1202 may comprise another model chiplet 402 for model chiplet testing, another DUT chiplet 502 for parallel testing, or a chiplet that interoperates with the DUT chiplet 502 to enhance testing for the DUT chiplet 502. Embodiments are not limited in this context.

FIG. 16 illustrates a system 1600. As previously discussed, UCIe supports two broad usage models. The first is package level integration to deliver power-efficient and cost-effective performance, as described with reference to system 100. The second usage is to provide off-package connectivity using different type of media (e.g., optical, electrical cable, mmWave) using UCIe retimers to transport the underlying protocols (e.g., PCIe, CXL) at the rack or even the pod level for enabling resource pooling, resource sharing, and even message passing using load-store semantics beyond the node level to the rack/ pod level to derive better power-efficient and cost-effective performance at the edge and data centers.

The system 1600 illustrates an example architecture for the second usage. System 1600 includes a DUT chiplet 502 that is designed and built to be compliant with the UCIe Specification. Instead of the DUT chiplet 502 integrated into a semiconductor die or semiconductor package for UCIe functionality, the DUT chiplet 502 may include one or more UCIe retimers 1612. The UCIe retimers 1612 may communicate with various server-level compute, memory and communications resources implemented by various server sleds, such as a pooled memory sled 1602 and one or more computes such as compute sled 1604, compute sled 1606 and compute sled 1608.

In one embodiment, the model chiplet 402 may be used in a test system to test a DUT chiplet 502 suitable for use in the system 1600 or alternative systems and configurations. Embodiments are not limited in this context.

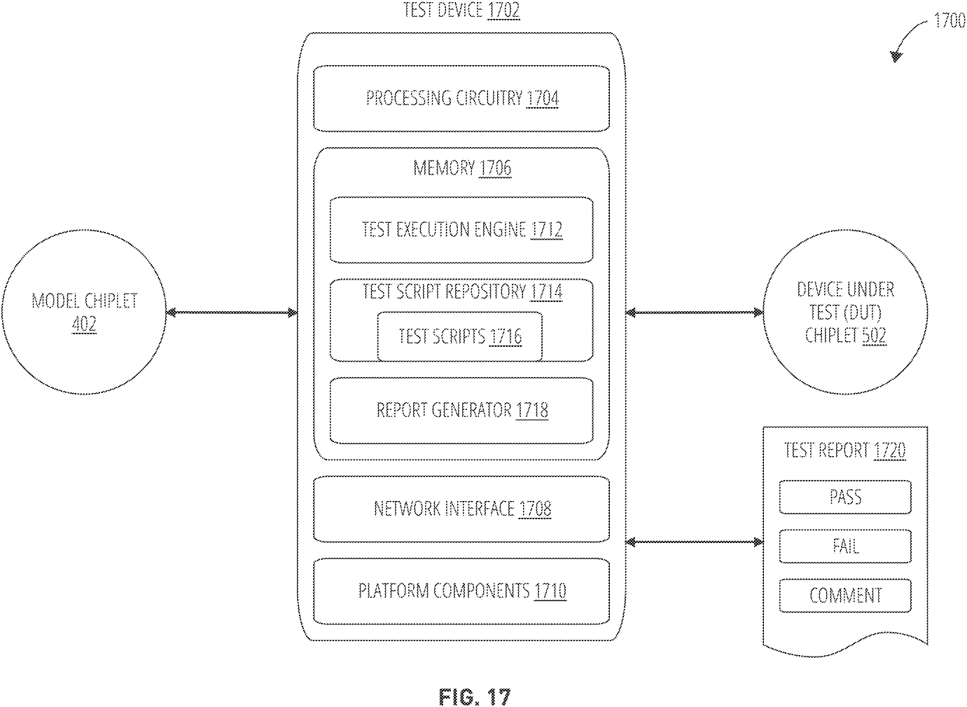

FIG. 17 illustrates a test system 1700 suitable for testing the model chiplet 402 and the DUT chiplet 502. In one embodiment, for example, the test system 1700 may be implemented as automated testing equipment (ATE). Overall, ATE plays a critical role in ensuring the quality and reliability of semiconductor devices, which is essential for their successful integration into electronic products.

ATE is a type of electronic testing equipment used in semiconductor manufacturing to test and validate the performance of semiconductor devices or integrated circuits (ICs). ATE systems are designed to perform a variety of tests on semiconductor chips including functional tests, parametric tests, and reliability tests. These tests ensure that the chips meet the required specifications and standards before they are shipped to customers. ATE systems typically consist of a test head or probe, which makes contact with the device under test (DUT), and a test instrument, which generates the test signals and measures the DUT’s response. The test instrument may include instruments such as digital multimeters, oscilloscopes, and logic analyzers, and may also include specialized instruments such as radio frequency (RF) analyzers and signal generators.

ATE systems are capable of testing multiple chips simultaneously, which increases testing efficiency and reduces manufacturing costs. They can also be programmed to run automated test sequences, which reduces the risk of human error and improves test consistency.

ATE systems are used in various stages of the semiconductor manufacturing process, including wafer sort, final test, and burn-in. Wafer sort is the process of testing individual chips on a wafer before they are separated and packaged, while final test is performed on the packaged devices. Burn-in is a stress test performed on chips to identify potential reliability issues.

The test system 1700 may comprise ATE having a test device 1702. The test device 1702 may comprise, in general, a computing device such as a computer, a laptop computer, a virtual machine, a desktop computer, workstation, server, server blade, cloud computer, and other compute systems with sufficient processing power and memory to test a chiplet such as the model chiplet 402 or the DUT chiplet 502.

As depicted in FIG. 17, the test device 1702 may include processing circuitry 1704, memory 1706, a network interface 1708, and other platform components 1710. An example of a test device 1702 and respective components is described with reference to the computing system 2300.

The test device 1702 may connect with the model chiplet 402 and the DUT chiplet 502 via a test head or probe, which makes contact with the model chiplet 402 and the DUT chiplet 502 either directly or indirectly through the test package 600. For instance, the test device 1702 can connect to the individual units using a set of microscopic needles. Once the chips are sawn apart and packaged, the test head or probe can connect to the chips using zero insertion force (ZIF) sockets, sometimes called contactors. A ZIF socket is a type of integrated circuit (IC) socket or electrical connector that requires very little (but not literally zero) force for insertion.

Once connected, the test device 1702 may execute instructions stored in memory 1706 for a test execution engine 1712. The test execution engine 1712 can access test scripts 1716 stored in a test script repository 1714. The test execution engine 1712 can execute one or more test scripts 1716 to perform various programmed tests associated with features or functions defined by the UCIe Specification for the DUT chiplet 502, and generate result information such as measurements or test values. In one example, a test script 1716 may be coded to perform UCIe-related tests using the model test logic 414, the DUT test logic 514, the adapter 724, or logic to manipulate the UCIe register values as defined in Table 1. A test script 1716 may also be coded for specific testing methodologies for UCIe testing as described with reference to FIGS. 18 and 19 described below.

The test execution engine 1712 may receive or access a well-defined set of semiconductor specifications. The specifications may include electrical specifications, logical specifications, protocol specifications (e.g., PCIe, CXL, etc.), software specifications, form-factor specifications, management specifications, and so forth. The test execution engine 1712 may receive or access one or more test criteria based on the semiconductor specifications, such as test definitions, pass or fail criteria, electrical, logical, protocol, software, and so forth. The test execution engine 1712 may manage, control or access a set of test tools, such as connectors, and execute procedures such as test scripts 1716, to test hardware and software associated with the model chiplet 402, the DUT chiplet 502, the test package 600, or any combination thereof. The test execution engine 1712 may compare test result information for the hardware or the software against the test criteria to validate or invalidate compliance or interoperability with the semiconductor specifications.

The memory may also store instructions for a report generator 1718. The report generator 1718 may receive result information from the test execution engine 1712, and generate a test report 1720 based on the result information with results from the testing procedures and potential recommendations to correct any noted deficiencies. The test report 1720 may provide clear test output of whether the DUT chiplet 502 passes or fails validation testing.

In one embodiment, for example, the processing circuitry 1704 of the test device 1702 may execute instructions for the test execution engine 1712. The test execution engine 1712 may send a control instruction to a model chiplet 402 to initiate semiconductor testing using a test script 1716 stored in the test script repository 1714. The model chiplet 402 may comprise a model logic feature 412 that is a known good model (KGM) of a logic feature defined by a semiconductor specification, such as the UCIe Specification, among others. The test execution engine 1712 of the test device 1702 may receive a measurement from the model chiplet 402 in response to the control instruction to initiate semiconductor testing. The measurement may be associated with a DUT logic feature 512 of a DUT chiplet 502. The DUT logic feature 512 may comprise an unknown good model (UGM) of the logic feature defined by the semiconductor specification, such as the UCIe Specification. The test execution engine 1712 may compare the measurement for the DUT logic feature 512 to an evaluation criterion to form result information. The evaluation criterion may be defined by the semiconductor specification, such as the UCIe Specification. The report generator 1718 may determine whether the DUT logic feature meets the evaluation criterion of the semiconductor specification based on the result information, and output a test report 1720 with the test results. The test results may indicate whether the tested DUT logic feature 512 passes and is in compliance with a corresponding feature defined by the UCIe Specification, or fails and is not in compliance with the corresponding feature defined by the UCIe Specification. The test report 1720 may also have one or more comments and/or recommendations associated with the tested DUT logic feature 512.

FIG. 18 illustrates a more detailed view of the DUT chiplet 502. As shown in FIG. 18, the DUT chiplet 502 may have a set of DUT logic features 512 and a set of DUT test logic 514.

The DUT logic features 512 may include a physical layer 1802 similar to physical layer 306 as implemented with a PHY configuration 1040 with one or more UCIe PHYS. The DUT logic features 512 may include a UCIe adapter 724 similar to the die-to-die adapter 304 as implemented with the adapter data path 1116 and the compliance FLIT injector 1108. The DUT logic features 512 may include a UCIe protocol layer 1804 similar to the protocol layer 302. The DUT logic features 512 may include other UCIe features, functionality and IP blocks as needed for a given implementation. Embodiments are not limited in this context.

The DUT test logic 514 may include various test logic or components to assist in testing the DUT chiplet 502. The DUT test logic 514 may include one or more of a compliance manager 1806, a header manager 1808, a pattern generator 1810, a state manager 1812, a protocol manager 1814 and a graph manager 1816. The DUT test logic 514 may include other UCIe test logic or components as needed for a given implementation. Embodiments are not limited in this context.

In one embodiment, the DUT test logic 514 may include one or more of a compliance manager 1806. The compliance manager 1806 may control whether the DUT chiplet 502 is to enter a compliance mode or test mode, which is setup via a configuration register. When in compliance mode, the DUT chiplet 502 does not forward any FLITs to the protocol layer, and does not accept any FLITs from the protocol layer. Software will set this bit before beginning UCIe Link training.

In one embodiment, the DUT test logic 514 may include one or more of a header manager 1808. The header manager 1808 may modify a FLIT header when operating in the compliance mode. The modified FLIT header may be used to differentiate FLITs that go through the transmission retry buffer 1104 of the adapter 724, and those that do not go through the transmission retry buffer 1104.

In one embodiment, the DUT test logic 514 may include one or more of a pattern generator 1810. The pattern generator 1810 may generate one or more test patterns for the compliance FLIT injector 1108 of the adapter 724. The compliance FLIT injector 1108 allows the adapter 724 to have the capability to inject a set of test FLITs 1118 into the adapter data path 1116, including both no operation (NOP) and non-NOP FLITs (e.g., operation FLITs). For non-NOP FLITs, the compliance FLIT injector 1108 of the adapter 724 may support pattern injections in the protocol related bytes of the FLIT. Examples for test patterns may include: (1) all 0 bytes; (2) a 4 byte pattern determined from a configuration register; and (3) a clock pattern in every byte such as an alternation 1b and 0b within each byte. The compliance FLIT injector 1108 of the adapter 724 may also have the capability to offset the injected patterns across bytes. For example, byte 1 has the same injected pattern as byte 0 but offset in time by a fixed number of clock cycles. The compliance FLIT injector 1108 may generate the test FLITs 1118 in a test pattern suitable for testing a DUT logic feature 512.

In one embodiment, the DUT test logic 514 may include one or more of a state manager 1812. The state manager 1812 manages RDI state machines for the adapter 724 and physical layer 1802 RDI state machines. The state manager 1812 may manage state transitions for all the states provided in the UCIe Specification, such as Reset, Active, L1, L2, Retrain, LinkReset, LinkError, Disabled, and so forth.

In one embodiment, the DUT test logic 514 may include one or more of a protocol manager 1814. As previously discussed, the protocol layer 1804 may support multiple protocols, such as PCIe, CXL, streaming protocol, and so forth. The protocol manager 1814 may modify the other DUT test logic 514 with appropriate hooks as needed to test the DUT chiplet 502 when using the different protocols.

In one embodiment, the DUT test logic 514 may include one or more of a graph manager 1816. The graph manager 1816 may manage different combinations of hardware and/or software driven graphical displays of the different test patterns for compliance testing. An example of graphs may include a shmoo plot across FLITs, or across bytes within a FLIT to exercise different patterns across the lanes, or other hardware and/or software features. A shmoo plot is a graphical display of the response of a component or system varying over a range of conditions or inputs.

In one embodiment, the DUT test logic 514 may include other UCIe test logic or components as needed for a given implementation. For example, in one embodiment, the DUT test logic 514 may include all or some of the model test logic 414, such as one or more of a pattern generator 1906, a loopback manager 1908, a droop detector 1910, a process monitor 1912, an oscilliscope 1914, or a ring oscillator 1916. In this manner, the DUT test logic 514 may allow the DUT chiplet 502 to have all the capabilities of the model chiplet 402. Embodiments are not limited in this context.

FIG. 19 illustrates a more detailed view of the model chiplet 402. As shown in FIG. 19, the model chiplet 402 may have a set of DUT model logic features 412 and a set of DUT model test logic 414.

The model logic features 412 may include a physical layer 1902 similar to physical layer 306 as implemented with a PHY configuration 902 with one or more UCIe PHYS. The model logic features 412 may include a UCIe adapter 724 similar to the die-to-die adapter 304 as implemented with the adapter data path 1116 and the compliance FLIT injector 1108. The model logic features 412 may include a UCIe protocol layer 1904 similar to the protocol layer 302. The model logic features 412 may include other UCIe features, functionality and IP blocks as needed for a given implementation. Embodiments are not limited in this context.

The model test logic 414 may include various test logic or components to assist in testing the DUT chiplet 502. In one embodiment, the model test logic 414 may include one or more of a pattern generator 1906, a loopback manager 1908, a droop detector 1910, a process monitor 1912, an oscilliscope 1914, and a ring oscillator 1916. The model test logic 414 may include other UCIe test logic or components as needed for a given implementation. Embodiments are not limited in this context.

In one embodiment, the model test logic 414 may include one or more of a pattern generator 1906. The pattern generator 1906 may be the same or similar to the pattern generator 1810 of the DUT test logic 514. The pattern generator 1906 may generate one or more test patterns for the compliance FLIT injector 1108 of the adapter 724. The compliance FLIT injector 1108 allows the adapter 724 to have the capability to inject a set of test FLITs 1118 into the adapter data path 1116, including both no operation (NOP) and non-NOP FLITs (e.g., operation FLITs). For non-NOP FLITs, the compliance FLIT injector 1108 of the adapter 724 may support pattern injections in the protocol related bytes of the FLIT. Examples for test patterns may include: (1) all 0 bytes; (2) a 4 byte pattern determined from a configuration register; and (3) a clock pattern in every byte such as an alternation 1b and 0b within each byte. The compliance FLIT injector 1108 of the adapter 724 may also have the capability to offset the injected patterns across bytes. For example, byte 1 has the same injected pattern as byte 0 but offset in time by a fixed number of clock cycles. The compliance FLIT injector 1108 may generate the test FLITs 1118 in a test pattern suitable for testing a DUT logic feature 512.

In addition, the pattern generator 1906 may generate additional test patterns for the DUT chiplet 502. For example, the pattern generator 1906 may generate extra test patterns per lane to test victim versus aggressor scenarios, fully characterize cross-talk between lanes, and other custom test patterns for the DUT chiplet 502.

In one embodiment, the model test logic 414 may include one or more of a loopback manager 1908. The loopback manager 1908 may implement or manage a loopback for the model chiplet 402. A loopback is the routing of electronic signals back to their source without intentional processing or modification. It is primarily a means of testing the communications infrastructure. In one embodiment, the loopback may be a PCIe-type loopback such as a Far End Loop Back (FELB), among other types of loopbacks. The loopback manager 1908 may allows the model chiplet 402 to do victim or aggressor sweeps or implement customized patterns to fully enable tester-like rich patterns for full corner-case characterization. The loopback manager 1908 may also provide the model chiplet 402 the ability to use sideband channel comments, instructions, or communication to control analog bits or controls of the DUT chiplet 502. For example, the model chiplet 402 may manage override on-die termination, duty cycle adjusters, phase interpolators, lane to lane deskew, delay locked loops, and so forth.

In one embodiment, the model test logic 414 may include one or more of a droop detector 1910. The droop detector 1910 may comprise or implement on-die power droop measurement hardware and derive supply sensitivity for the model chiplet 402 and/or the DUT chiplet 502. In one embodiment, the DUT chiplet 502 may also implement a droop detector 1910.

In one embodiment, the model test logic 414 may include one or more of a process monitor 1912. The process monitor 1912 may monitor one or more processes associated with the model chiplet 402 and/or the DUT chiplet 502. In one embodiment, the DUT chiplet 502 may also implement a process monitor 1912.

In one embodiment, the model test logic 414 may include one or more of an oscilliscope 1914. The oscilliscope 1914 may be an on-die oscillicope or equivalent hardware as in the form of high-speed analog to digital converters (ADCs) or similar hardware. The oscilliscope 1914 can be used to characterize features such as jitter or voltage levels at different hardware points of test on both the model chiplet 402 as well as the DUT chiplet 502.

In one embodiment, the model test logic 414 may include one or more of a ring oscillator 1916. The ring oscillator 1916 may run at an asynchronous frequency to a link master clock that is neither the same frequency as the link master clock nor a harmonic frequency of the link master clock. The ring oscillator 1916 may use a sampling method over time to characterize certain parameters such as duty cycles at different hardware points of interest.

The model test logic 414 may include other UCIe test logic or components as needed for a given implementation. For example, in one embodiment, the model test logic 414 may include all or some of the DUT test logic 514, such as one or more of a compliance manager 1806, a header manager 1808, a pattern generator 1810, a state manager 1812, a protocol manager 1814, or a graph manager 1816. In this manner, the model test logic 414 may allow the model chiplet 402 to have all the capabilities of the DUT chiplet 502. Embodiments are not limited in this context.

The model test logic 414 may include logic to allow electrical parameter testing for the model chiplet 402 and/or the DUT chiplet 502. Examples of electrical parameter testing may include without limitation electrical parameters such as eye height and eye width characterization, bit error rate (BER) testing and extrapolation method, receiver input common mode range, lane to lane skew for both receive (RX) and transmit (TX) lane clusters with the PHY, PHY to PHY skew, termination values for both driver and receiver, even/odd eye symmetry measurements, TX swing, TX Bandwidth, TX and RX equalization (EQ), channel characterization for both standard laminate channels as well as advanced channels such as silicon interposers, silicon bridges, fan-out technologies, and pad cap, among other electrical parameters.

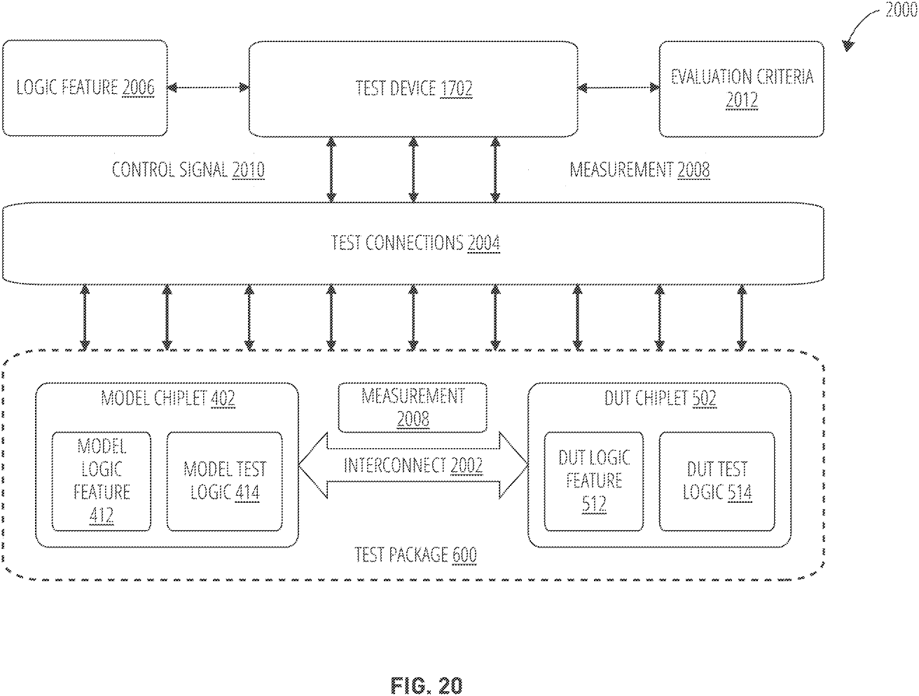

FIG. 20 illustrates a test system 2000. The test system 2000 may be a more detailed view of the test system 1700. The test system 2000 may include the test device 1702 coupled to a set of test connections 2004. The test connections 2004 may comprise one or more test heads or probes as previously discussed. The test connections 2004 may be coupled to the test package 600. The test package 600 may comprise the model chiplet 402 and the DUT chiplet 502 communicating signals via the interconnect 206, which may be implemented using the reference channels 604 either embedded in the substrate 602 or in silicon bridges 1302, 1304, 1504 or 1506.

As previously described, the test device 1702 may include a test execution engine 1712. The test execution engine 1712 may receive an instruction to test a logic feature 2006 as defined in the UCIe Specification. For example, the logic feature 2006 may be presented in a graphical user interface (GUI) and selected by a human operator, such as a tester. In another example, the logic feature 2006 may be automatically selected via a test script 1716 executed by the test device 1702. The test execution engine 1712 may send a control signal 2010 to a model chiplet 402 via the test connections 2004. The control signal 2010 may be an instruction to initiate semiconductor testing using a test script 1716 stored in the test script repository 1714.

The model chiplet 402 may include a test interface 416, a model logic feature 412 and model test logic 414. The model logic feature 412 may comprise a known good model (KGM) for a logic feature in accordance with a semiconductor specification, such as the UCIe Specification, among others. The model test logic 414 may receive a control signal 2010 from the test interface 416, where the control signal 2010 initiates testing of a DUT logic feature 512 of a DUT chiplet 502. The model chiplet 402 may send test information over an interconnect 2002 in response to the control signal. The test information may be designed to test the DUT logic feature 512 of the DUT chiplet 502. For instance, the model chiplet 402 may implement an adapter 724 with a compliance FLIT injector 1108 to generate and inject test FLITs 1118 in a test pattern designed for the DUT logic feature 512. The model chiplet 402 may receive response information over the interconnect in response to the test information, the response information associated with the DUT logic feature 512 of the DUT chiplet 502. The model chiplet 402 may receive or generate a measurement 2008 for the DUT logic feature 512 based on the response information, and send the measurement 2008 for the DUT logic feature 512 to the test interface 416.

The test execution engine 1712 of the test device 1702 may receive a measurement 2008 from the test interface 416 of the model chiplet 402 in response to the control instruction to initiate semiconductor testing. The measurement 2008 may be associated with a DUT logic feature 512 of a DUT chiplet 502. The DUT logic feature 512 may comprise an unknown good model (UGM) of the logic feature defined by the semiconductor specification, such as the UCIe Specification.

The test execution engine 1712 may compare the measurement 2008 for the DUT logic feature 512 to an evaluation criterion to form result information. The evaluation criterion may be defined by the semiconductor specification, such as the UCIe Specification. The report generator 1718 may determine whether the DUT logic feature 512 meets the evaluation criterion of the semiconductor specification based on the result information, and output a test report 1720 with the test results. The test results may indicate whether the tested DUT logic feature 512 passes and is in compliance with a corresponding feature defined by the UCIe Specification, or fails and is not in compliance with the corresponding feature defined by the UCIe Specification. The test report 1720 may also have one or more comments and/or recommendations associated with the tested DUT logic feature 512.

Operations for the disclosed embodiments may be further described with reference to the following figures. Some of the figures may include a logic flow. Although such figures presented herein may include a particular logic flow, it can be appreciated that the logic flow merely provides an example of how the general functionality as described herein can be implemented. Further, a given logic flow does not necessarily have to be executed in the order presented unless otherwise indicated. Moreover, not all acts illustrated in a logic flow may be required in some embodiments. In addition, the given logic flow may be implemented by a hardware element, a software element executed by a processor, or any combination thereof. The embodiments are not limited in this context.

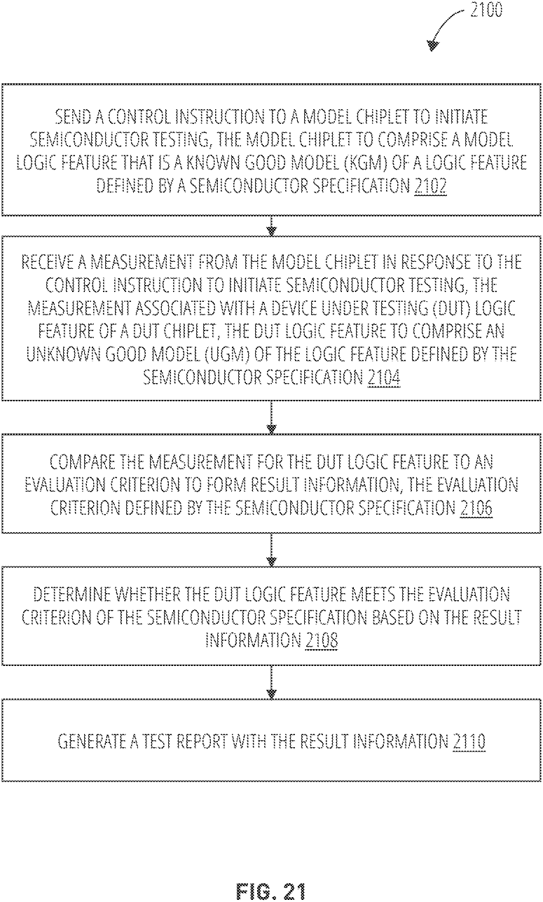

FIG. 21 illustrates an embodiment of a logic flow 2100. The logic flow 2100 may be representative of some or all of the operations executed by one or more embodiments described herein. For example, the logic flow 2100 may include some or all of the operations performed by devices or entities within the system 100 or the system 200. More particularly, the logic flow 2100 illustrates an example where the test device 1702 in the test system 1700 performs a test for a DUT chiplet 502 using a model chiplet 402.

In block 2102, logic flow 2100 sends a control signal to a model chiplet to initiate semiconductor testing, the model chiplet to comprise a model logic feature that is a known good model (KGM) of a logic feature defined by a semiconductor specification. For example, the test device 1702 may receive a logic feature 2006 from a graphical user interface (GUI). The test device 1702 may also receive a selection of a test script 1716 to test the logic feature 2006 from the GUI. The logic feature 2006 and/or the test script 1716 may be selected by a tester. Alternatively, a tester may select a test script 1716 and the test script 1716 may select the logic feature 2006 to test. In one embodiment, the test device 1702 may be part of ATE in a semiconductor processing fabrication plant to automatically test the DUT chiplet 502 without human intervention. In this embodiment, the test device 1702 may be pre-programmed to execute one or more of the test scripts 1716 to test one or more logic features 2006 of the DUT chiplet 502.

Once the logic features 2006 and the test scripts 1716 are selected, a test execution engine 1712 may execute the test scripts 1716 to begin testing of the logic features 2006. The test execution engine 1712 and/or the executing test script 1716 of the test device 1702 sends a control signal 2010 to a model chiplet 402 to initiate semiconductor testing, the model chiplet 402 to comprise a model logic feature 412 that is a known good model (KGM) of a logic feature 2006 defined by a semiconductor specification, such as the UCIe Specification, among others.

In block 2104, logic flow 2100 receives a measurement from the model chiplet in response to the control signal to initiate semiconductor testing, the measurement associated with a device under testing (DUT) logic feature of a DUT chiplet, the DUT logic feature to comprise an unknown good model (UGM) of the logic feature defined by the semiconductor specification. For example, the model chiplet 402 receives a measurement 2008 from the model chiplet 402 in response to the control instruction to initiate semiconductor testing, the measurement 2008 associated with a DUT logic feature 512 of a DUT chiplet 502, the DUT logic feature 512 to comprise an unknown good model (UGM) of the logic feature 2006 defined by the UCIe Specification.

In block 2106, logic flow 2100 compares the measurement for the DUT logic feature to an evaluation criterion to form result information, the evaluation criterion defined by the semiconductor specification. For example, the test execution engine 1712 compares the measurement 2008 for the DUT logic feature 512 to one or more evaluation criteria 2012 to form result information, the evaluation criteria 2012 defined by the UCIe Specification.

In block 2108, logic flow 2100 determines whether the DUT logic feature meets the evaluation criterion of the semiconductor specification based on the result information. For example, the test execution engine 1712 determines whether the DUT logic feature 512 meets the evaluation criteria 2012 of the semiconductor specification based on the result information. The report report generator 1718 may generate a test report 1720 with the test results, such as whether the DUT logic feature 512 of the DUT chiplet 502 passes or fails the semiconductor testing.

In block 2110, logic flow 2100 generates a test report with the result information. For example, the report generator 1718 may generate a test report 1720 to indicate whether the DUT logic feature 512 passes the semiconductor testing and is in compliance with the semiconductor specification, or fails the semiconductor testing and is not in compliance with the semiconductor specification.

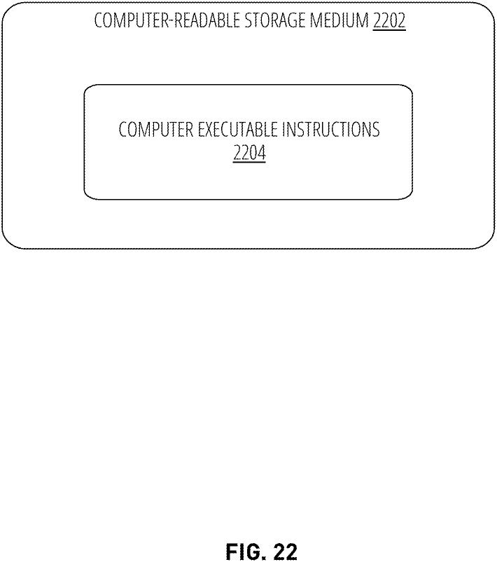

FIG. 22 illustrates an apparatus 2200. Apparatus 2200 may comprise any non-transitory computer-readable storage medium 2202 or machine-readable storage medium, such as an optical, magnetic or semiconductor storage medium. In various embodiments, apparatus 2200 may comprise an article of manufacture or a product. In some embodiments, the computer-readable storage medium 2202 may store computer executable instructions with which circuitry can execute. For example, computer executable instructions 2204 can include instructions to implement operations described with respect to any logic flows described herein. Examples of computer-readable storage medium 2202 or machine-readable storage medium may include any tangible media capable of storing electronic data, including volatile memory or non-volatile memory, removable or non-removable memory, erasable or non-erasable memory, writeable or re-writeable memory, and so forth. Examples of computer executable instructions 2204 may include any suitable type of code, such as source code, compiled code, interpreted code, executable code, static code, dynamic code, object-oriented code, visual code, and the like.

FIG. 3 illustrates an embodiment of a computing architecture 2300. Computing architecture 2300 is a computer system with multiple processor cores such as a distributed computing system, supercomputer, high-performance computing system, computing cluster, mainframe computer, mini-computer, client-server system, personal computer (PC), workstation, server, portable computer, laptop computer, tablet computer, handheld device such as a personal digital assistant (PDA), or other device for processing, displaying, or transmitting information. Similar embodiments may comprise, e.g., entertainment devices such as a portable music player or a portable video player, a smart phone or other cellular phone, a telephone, a digital video camera, a digital still camera, an external storage device, or the like. Further embodiments implement larger scale server configurations. In other embodiments, the computing architecture 2300 may have a single processor with one core or more than one processor. Note that the term “processor” refers to a processor with a single core or a processor package with multiple processor cores. In at least one embodiment, the computing computing architecture 2300 is representative of the components of the system 100. More generally, the computing computing architecture 2300 is configured to implement all logic, systems, logic flows, methods, apparatuses, and functionality described herein with reference to previous figures.

As used in this application, the terms “system” and “component” and “module” are intended to refer to a computer-related entity, either hardware, a combination of hardware and software, software, or software in execution, examples of which are provided by the exemplary computing architecture 2300. For example, a component can be, but is not limited to being, a process running on a processor, a processor, a hard disk drive, multiple storage drives (of optical and/or magnetic storage medium), an object, an executable, a thread of execution, a program, and/or a computer. By way of illustration, both an application running on a server and the server can be a component. One or more components can reside within a process and/or thread of execution, and a component can be localized on one computer and/or distributed between two or more computers. Further, components may be communicatively coupled to each other by various types of communications media to coordinate operations. The coordination may involve the uni-directional or bi-directional exchange of information. For instance, the components may communicate information in the form of signals communicated over the communications media. The information can be implemented as signals allocated to various signal lines. In such allocations, each message is a signal. Further embodiments, however, may alternatively employ data messages. Such data messages may be sent across various connections. Exemplary connections include parallel interfaces, serial interfaces, and bus interfaces.

As shown in FIG. 3, computing architecture 2300 comprises a system-on-chip (SoC) 2302 for mounting platform components. System-on-chip (SoC) 2302 is a point-to-point (P2P) interconnect platform that includes a first processor 2304 and a second processor 2306 coupled via a point-to-point interconnect 2370 such as an Ultra Path Interconnect (UPI). In other embodiments, the computing architecture 2300 may be of another bus architecture, such as a multi-drop bus. Furthermore, each of processor 2304 and processor 2306 may be processor packages with multiple processor cores including core(s) 2308 and core(s) 2310, respectively. While the computing architecture 2300 is an example of a two-socket (2S) platform, other embodiments may include more than two sockets or one socket. For example, some embodiments may include a four-socket (4S) platform or an eight-socket (8S) platform. Each socket is a mount for a processor and may have a socket identifier. Note that the term platform may refers to a motherboard with certain components mounted such as the processor 2304 and chipset 2332. Some platforms may include additional components and some platforms may only include sockets to mount the processors and/or the chipset. Furthermore, some platforms may not have sockets (e.g. SoC, or the like). Although depicted as a SoC 2302, one or more of the components of the SoC 2302 may also be included in a single die package, a multi-chip module (MCM), a multi-die package, a chiplet, a bridge, and/or an interposer. Therefore, embodiments are not limited to a SoC.

The processor 2304 and processor 2306 can be any of various commercially available processors, including without limitation an Intel® Celeron®, Core®, Core (2) Duo®, Itanium®, Pentium®, Xeon®, and XScale® processors; AMD® Athlon®, Duron® and Opteron® processors; ARM® application, embedded and secure processors; IBM® and Motorola® DragonBall® and PowerPC® processors; IBM and Sony® Cell processors; and similar processors. Dual microprocessors, multi-core processors, and other multi-processor architectures may also be employed as the processor 2304 and/or processor 2306. Additionally, the processor 2304 need not be identical to processor 2306.

Processor 2304 includes an integrated memory controller (IMC) 2320 and point-to-point (P2P) interface 2324 and P2P interface 2328. Similarly, the processor 2306 includes an IMC 2322 as well as P2P interface 2326 and P2P interface 2330. IMC 2320 and IMC 2322 couple the processor 2304 and processor 2306, respectively, to respective memories (e.g., memory 2316 and memory 2318). Memory 2316 and memory 2318 may be portions of the main memory (e.g., a dynamic random-access memory (DRAM)) for the platform such as double data rate type 4 (DDR4) or type 5 (DDR5) synchronous DRAM (SDRAM). In the present embodiment, the memory 2316 and the memory 2318 locally attach to the respective processors (i.e., processor 2304 and processor 2306). In other embodiments, the main memory may couple with the processors via a bus and shared memory hub. Processor 2304 includes registers 2312 and processor 2306 includes registers 2314.

Computing architecture 2300 includes chipset 2332 coupled to processor 2304 and processor 2306. Furthermore, chipset 2332 can be coupled to storage device 2350, for example, via an interface (I/F) 2338. The I/F 2338 may be, for example, a Peripheral Component Interconnect-enhanced (PCIe) interface, a Compute Express Link® (CXL) interface, or a Universal Chiplet Interconnect Express (UCIe) interface. Storage device 2350 can store instructions executable by circuitry of computing architecture 2300 (e.g., processor 2304, processor 2306, GPU 2348, accelerator 2354, vision processing unit 2356, or the like). For example, storage device 2350 can store instructions for server device 102,, client devices 112, client devices 116, or the like.

Processor 2304 couples to the chipset 2332 via P2P interface 2328 and P2P 2334 while processor 2306 couples to the chipset 2332 via P2P interface 2330 and P2P 2336. Direct media interface (DMI) 2376 and DMI 2378 may couple the P2P interface 2328 and the P2P 2334 and the P2P interface 2330P2P 2336, respectively. DMI 2376 and DMI 2378 may be a high-speed interconnect that facilitates, e.g., eight Giga Transfers per second (GT/s) such as DMI 3.0. In other embodiments, the processor 2304 and processor 2306 may interconnect via a bus.

The chipset 2332 may comprise a controller hub such as a platform controller hub (PCH). The chipset 2332 may include a system clock to perform clocking functions and include interfaces for an I/O bus such as a universal serial bus (USB), peripheral component interconnects (PCIs), CXL interconnects, UCIe interconnects, interface serial peripheral interconnects (SPIs), integrated interconnects (I2Cs), and the like, to facilitate connection of peripheral devices on the platform. In other embodiments, the chipset 2332 may comprise more than one controller hub such as a chipset with a memory controller hub, a graphics controller hub, and an input/output (I/O) controller hub.

In the depicted example, chipset 2332 couples with a trusted platform module (TPM) 2344 and UEFI, BIOS, FLASH circuitry 2346 via I/F 2342. The TPM 2344 is a dedicated microcontroller designed to secure hardware by integrating cryptographic keys into devices. The UEFI, BIOS, FLASH circuitry 2346 may provide pre-boot code. The I/F 2342 may also be coupled to a network interface circuit (NIC) 2380 for connections off-chip.

Furthermore, chipset 2332 includes the I/F 2338 to couple chipset 2332 with a high-performance graphics engine, such as, graphics processing circuitry or a graphics processing unit (GPU) 2348. In other embodiments, the computing architecture 2300 may include a flexible display interface (FDI) (not shown) between the processor 2304 and/or the processor 2306 and the chipset 2332. The FDI interconnects a graphics processor core in one or more of processor 2304 and/or processor 2306 with the chipset 2332.

The computing architecture 2300 is operable to communicate with wired and wireless devices or entities via the network interface (NIC) 180 using the IEEE 802 family of standards, such as wireless devices operatively disposed in wireless communication (e.g., IEEE 802.11 over-the-air modulation techniques). This includes at least Wi-Fi (or Wireless Fidelity), WiMax, and Bluetooth™ wireless technologies, 3G, 4G, LTE wireless technologies, among others. Thus, the communication can be a predefined structure as with a conventional network or simply an ad hoc communication between at least two devices. Wi-Fi networks use radio technologies called IEEE 802.11x (a, b, g, n, ac, ax, etc.) to provide secure, reliable, fast wireless connectivity. A Wi-Fi network can be used to connect computers to each other, to the Internet, and to wired networks (which use IEEE 802.3-related media and functions).

Additionally, accelerator 2354 and/or vision processing unit 2356 can be coupled to chipset 2332 via I/F 2338. The accelerator 2354 is representative of any type of accelerator device (e.g., a data streaming accelerator, cryptographic accelerator, cryptographic coprocessor, an offload engine, etc.). One example of an accelerator 2354 is the Intel® Data Streaming Accelerator (DSA). The accelerator 2354 may be a device including circuitry to accelerate copy operations, data encryption, hash value computation, data comparison operations (including comparison of data in memory 2316 and/or memory 2318), and/or data compression. For example, the accelerator 2354 may be a USB device, PCI device, PCIe device, CXL device, UCIe device, and/or an SPI device. The accelerator 2354 can also include circuitry arranged to execute machine learning (ML) related operations (e.g., training, inference, etc.) for ML models. Generally, the accelerator 2354 may be specially designed to perform computationally intensive operations, such as hash value computations, comparison operations, cryptographic operations, and/or compression operations, in a manner that is more efficient than when performed by the processor 2304 or processor 2306. Because the load of the computing architecture 2300 may include hash value computations, comparison operations, cryptographic operations, and/or compression operations, the accelerator 2354 can greatly increase performance of the computing architecture 2300 for these operations.

The accelerator 2354 may include one or more dedicated work queues and one or more shared work queues (each not pictured). Generally, a shared work queue is configured to store descriptors submitted by multiple software entities. The software may be any type of executable code, such as a process, a thread, an application, a virtual machine, a container, a microservice, etc., that share the accelerator 2354. For example, the accelerator 2354 may be shared according to the Single Root I/O virtualization (SR-IOV) architecture and/or theScalable I/O virtualization (S-IOV) architecture. Embodiments are not limited in these contexts. In some embodiments, software uses an instruction to atomically submit the descriptor to the accelerator 2354 via a non-posted write (e.g., a deferred memory write (DMWr)). One example of an instruction that atomically submits a work descriptor to the shared work queue of the accelerator 2354 is the ENQCMD command or instruction (which may be referred to as “ENQCMD” herein) supported by the Intel® Instruction Set Architecture (ISA). However, any instruction having a descriptor that includes indications of the operation to be performed, a source virtual address for the descriptor, a destination virtual address for a device-specific register of the shared work queue, virtual addresses of parameters, a virtual address of a completion record, and an identifier of an address space of the submitting process is representative of an instruction that atomically submits a work descriptor to the shared work queue of the accelerator 2354. The dedicated work queue may accept job submissions via commands such as the movdir64b instruction.

Various I/O devices 2360 and display 2352 couple to the bus 2372, along with a bus bridge 2358 which couples the bus 2372 to a second bus 2374 and an I/F 2340 that connects the bus 2372 with the chipset 2332. In one embodiment, the second bus 2374 may be a low pin count (LPC) bus. Various devices may couple to the second bus 2374 including, for example, a keyboard 2362, a mouse 2364 and communication devices 2366.

Furthermore, an audio I/O 2368 may couple to second bus 2374. Many of the I/O devices 2360 and communication devices 2366 may reside on the system-on-chip (SoC) 2302 while the keyboard 2362 and the mouse 2364 may be add-on peripherals. In other embodiments, some or all the I/O devices 2360 and communication devices 2366 are add-on peripherals and do not reside on the system-on-chip (SoC) 2302.

The components and features of the devices described above may be implemented using any combination of discrete circuitry, application specific integrated circuits (ASICs), logic gates and/or single chip architectures. Further, the features of the devices may be implemented using microcontrollers, programmable logic arrays and/or microprocessors or any combination of the foregoing where suitably appropriate. It is noted that hardware, firmware and/or software elements may be collectively or individually referred to herein as “logic” or “circuit.”

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

With general reference to notations and nomenclature used herein, the detailed descriptions herein may be presented in terms of program procedures executed on a computer or network of computers. These procedural descriptions and representations are used by those skilled in the art to most effectively convey the substance of their work to others skilled in the art.

A procedure is here, and generally, conceived to be a self-consistent sequence of operations leading to a desired result. These operations are those requiring physical manipulations of physical quantities. Usually, though not necessarily, these quantities take the form of electrical, magnetic or optical signals capable of being stored, transferred, combined, compared, and otherwise manipulated. It proves convenient at times, principally for reasons of common usage, to refer to these signals as bits, values, elements, symbols, characters, terms, numbers, or the like. It should be noted, however, that all of these and similar terms are to be associated with the appropriate physical quantities and are merely convenient labels applied to those quantities.

Further, the manipulations performed are often referred to in terms, such as adding or comparing, which are commonly associated with mental operations performed by a human operator. No such capability of a human operator is necessary, or desirable in most cases, in any of the operations described herein, which form part of one or more embodiments. Rather, the operations are machine operations. Useful machines for performing operations of various embodiments include general purpose digital computers or similar devices.

Some embodiments may be described using the expression “coupled” and “connected” along with their derivatives. These terms are not necessarily intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still co-operate or interact with each other.

Various embodiments also relate to apparatus or systems for performing these operations. This apparatus may be specially constructed for the required purpose or it may comprise a general purpose computer as selectively activated or reconfigured by a computer program stored in the computer. The procedures presented herein are not inherently related to a particular computer or other apparatus. Various general purpose machines may be used with programs written in accordance with the teachings herein, or it may prove convenient to construct more specialized apparatus to perform the required method steps. The required structure for a variety of these machines will appear from the description given.

What has been described above includes examples of the disclosed architecture. It is, of course, not possible to describe every conceivable combination of components and/or methodologies, but one of ordinary skill in the art may recognize that many further combinations and permutations are possible. Accordingly, the novel architecture is intended to embrace all such alterations, modifications and variations that fall within the spirit and scope of the appended claims.

The various elements of the devices as previously described with reference to FIG. 1-_ may include various hardware elements, software elements, or a combination of both. Examples of hardware elements may include devices, logic devices, components, processors, microprocessors, circuits, processors, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), memory units, logic gates, registers, semiconductor device, chips, microchips, chip sets, and so forth. Examples of software elements may include software components, programs, applications, computer programs, application programs, system programs, software development programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. However, determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that make the logic or processor. Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory unit, memory device, memory article, memory medium, storage device, storage article, storage medium and/or storage unit, for example, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, magneto-optical media, removable memory cards or disks, various types of Digital Versatile Disk (DVD), a tape, a cassette, or the like. The instructions may include any suitable type of code, such as source code, compiled code, interpreted code, executable code, static code, dynamic code, encrypted code, and the like, implemented using any suitable high-level, low-level, object-oriented, visual, compiled and/or interpreted programming language.

It will be appreciated that the exemplary devices shown in the block diagrams described above may represent one functionally descriptive example of many potential implementations. Accordingly, division, omission or inclusion of block functions depicted in the accompanying figures does not infer that the hardware components, circuits, software and/or elements for implementing these functions would necessarily be divided, omitted, or included in embodiments.

At least one computer-readable storage medium may include instructions that, when executed, cause a system to perform any of the computer-implemented methods described herein.

Some embodiments may be described using the expression “one embodiment” or “an embodiment” along with their derivatives. These terms mean that a particular feature, structure, or characteristic described in connection with the embodiment is included in at least one embodiment. The appearances of the phrase “in one embodiment” in various places in the specification are not necessarily all referring to the same embodiment. Moreover, unless otherwise noted the features described above are recognized to be usable together in any combination. Thus, any features discussed separately may be employed in combination with each other unless it is noted that the features are incompatible with each other.

The following examples pertain to further embodiments, from which numerous permutations and configurations will be apparent.

In one aspect, an apparatus, includes a model chiplet for semiconductor testing, the model chiplet having a test interface, a model logic feature and model test logic, the model logic feature to comprise a known good model (KGM) for a logic feature defined by a semiconductor specification, the model test logic to receive a control signal from the test interface, the control signal to initiate testing of a device under test (DUT) logic feature of a DUT chiplet, send test information over an interconnect in response to the control signal, the test information designed to test the DUT logic feature of the DUT chiplet, receive response information over the interconnect in response to the test information, the response information associated with the DUT logic feature of the DUT chiplet, generate a measurement for the DUT logic feature based on the response information, and send the measurement for the DUT logic feature to the test interface.

The apparatus may also include the model chiplet having multiple physical layer blocks, the physical layer blocks arranged in single-stack modules or double-stacked modules.

The apparatus may also include the model chiplet having multiple physical layer blocks, the physical layer blocks to comprise a size of 110 microns or 130 microns.

The apparatus may also include the model chiplet having a top side and a bottom side, the bottom side to comprise a set of bumps corresponding to a set of physical layer blocks, each bump to have a specific position on the bottom side according to a bump definition, each bump corresponding to each physical layer block.

The apparatus may also include the DUT chiplet having a top side and a bottom side, the bottom side to comprise a set of bumps corresponding to a set of physical layer blocks, each bump to have a specific position on the bottom side according to a bump definition, each bump corresponding to each physical layer block.

The apparatus may also include a substrate with a set of reference channels to provide a conductive path between the model chiplet and the DUT chiplet, the set of reference channels embedded in the substrate, the model chiplet and the DUT chiplet mounted on the substrate to form a standard test package.

The apparatus may also include a substrate with an embedded silicon bridge, the silicon bridge having a set of reference channels to provide a conductive path between the model chiplet and the DUT chiplet, the model chiplet and the DUT chiplet mounted on the substrate to form an advanced test package.

The apparatus may also include a substrate, an interposer mounted on the substrate, the interposer having a set of reference channels to provide a conductive path between the model chiplet and the DUT chiplet, the model chiplet and the DUT chiplet mounted on the interposer to form an advanced test package.

The apparatus may also include a substrate, an interposer mounted on the substrate, the interposer having a silicon bridge with a set of reference channels to provide a conductive path between the model chiplet and the DUT chiplet, the model chiplet and the DUT chiplet mounted on the interposer to form an advanced test package.

The apparatus may also include where the test interface is a serializer/deserializer (SerDes) interface.

The apparatus may also include where the logic feature is defined by a semiconductor specification, the semiconductor specification to comprise a die-to-die (D2D) on-package interconnect specification.

The apparatus may also include where the logic feature is defined by a semiconductor specification, the semiconductor specification to comprise a universal chiplet interconnect express (UCIe) specification.

The apparatus may also include where the logic feature includes a feature of a physical layer, an adapter or a protocol layer for an interconnect.

The apparatus may also include the model chiplet having logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the DUT chiplet.

The apparatus may also include the model chiplet having an adapter, the adapter to include a compliance flow control unit (FCU) level interface transfer (FLIT) injector, the compliance FLIT injector to generate a set of test FLITs in a test pattern to test the DUT chiplet.

The apparatus may also include the model test logic to comprise a pattern generator, a loopback generator, a droop detector, a process monitor, an oscilliscope, or a ring oscillator.

The apparatus may also include the DUT chiplet having a test interface, the DUT logic feature and DUT test logic, the DUT logic feature to comprise an unknown model for the logic feature in accordance with a semiconductor specification, the DUT test logic to receive the test information over the interconnect, generate the response information associated with the DUT logic feature, and send the response information over the interconnect to the model chiplet.

The apparatus may also include the DUT chiplet having logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the model chiplet.

The apparatus may also include the DUT chiplet having an adapter, the adapter to include a compliance flow control unit (FCU) level interface transfer (FLIT) injector, the compliance FLIT injector to generate a set of test FLITs in a test pattern to test the DUT chiplet.

The apparatus may also include the DUT chiplet having DUT test logic, the DUT test logic to comprise a compliance manager, a header manager, a pattern generator, a state manager, a protocol manager, or a graph manager.

The apparatus may also include the DUT chiplet having a UCIe retimer to communicate data to an off-chip device. Other technical features may be readily apparent to one skilled in the art from the following figures, descriptions, and claims.

In one aspect, a system, includes processing circuitry. The system also includes memory communicatively coupled to the processing circuitry, the memory to store instructions that when executed by the processing circuitry cause the processing circuitry to send a control signal to a model chiplet to initiate semiconductor testing, the model chiplet to comprise a model logic feature that is a known good model (KGM) of a logic feature defined by a semiconductor specification, receive a measurement from the model chiplet in response to the control signal to initiate semiconductor testing, the measurement associated with a device under testing (DUT) logic feature of a DUT chiplet, the DUT logic feature to comprise an unknown good model (UGM) of the logic feature defined by the semiconductor specification, compare the measurement for the DUT logic feature to an evaluation criterion to form result information, the evaluation criterion defined by the semiconductor specification, and determine whether the DUT logic feature meets the evaluation criterion of the semiconductor specification based on the result information.

The system may also include where the logic feature is defined by the semiconductor specification, the semiconductor specification to comprise a die-to-die (D2D) on-package interconnect specification.

The system may also include where the logic feature is defined by the semiconductor specification, the semiconductor specification to comprise a universal chiplet interconnect express (UCIe) specification.

The system may also include where the logic feature includes a feature of a physical layer, an adapter or a protocol layer for a semiconductor interconnect.

The system may also include the processing circuitry to generate a test report with the result information.

The system may also include a set of test connections communicatively coupled to the test device and a test package, the test package to comprise the model chiplet, the DUT chiplet and an interconnect to transmit signals between the model chiplet and the DUT chiplet, the test package to comprise a standard test package or an advanced test package.

The system may also include a test package coupled to the test device via a test connection, the test package having the model chiplet, the DUT chiplet and an interconnect to transmit signals between the model chiplet and the DUT chiplet, the test package to comprise a standard test package or an advanced test package.

The system may also include the model chiplet, the a model chiplet for semiconductor testing, the model chiplet having a test interface, a model logic feature and model test logic, the model logic feature to comprise a known good model (KGM) for a logic feature defined by a semiconductor specification

The system may also include where the logic feature is defined by the semiconductor specification, the semiconductor specification to comprise a die-to-die (D2D) on-package interconnect specification.

The system may also include where the logic feature is defined by the semiconductor specification, the semiconductor specification to comprise a universal chiplet interconnect express (UCIe) specification.

The system may also include the model chiplet having logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the DUT chiplet.

The system may also include the model chiplet having an adapter, the adapter to include a compliance flow control unit (FCU) level interface transfer (FLIT) injector, the compliance FLIT injector to generate a set of test FLITs in a test pattern to test the DUT chiplet.

The system may also include the model test logic to comprise a pattern generator, a loopback generator, a droop detector, a process monitor, an oscilliscope, or a ring oscillator.

The system may also include the DUT chiplet having a test interface, the DUT logic feature and DUT test logic, the DUT logic feature to comprise an unknown model for the logic feature in accordance with a semiconductor specification, the DUT test logic to receive the test information over the interconnect, generate the response information associated with the DUT logic feature, and send the response information over the interconnect to the model chiplet.

The system may also include the DUT chiplet having logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the model chiplet.

The system may also include the DUT chiplet having an adapter, the adapter to include a compliance flow control unit (FCU) level interface transfer (FLIT) injector, the compliance FLIT injector to generate a set of test FLITs in a test pattern to test the DUT chiplet.

The system may also include the DUT chiplet having DUT test logic, the DUT test logic to comprise a compliance manager, a header manager, a pattern generator, a state manager, a protocol manager, or a graph manager.

The system may also include the DUT chiplet having a UCIe retimer to communicate data to an off-chip device. Other technical features may be readily apparent to one skilled in the art from the following figures, descriptions, and claims.

In one aspect, a method, includes sending a control signal to a model chiplet to initiate semiconductor testing, the model chiplet to comprise a model logic feature that is a known good model (KGM) of a logic feature defined by a semiconductor specification, receiving a measurement from the model chiplet in response to the control signal to initiate semiconductor testing, the measurement associated with a device under testing (DUT) logic feature of a DUT chiplet, the DUT logic feature to comprise an unknown good model (UGM) of the logic feature defined by the semiconductor specification, comparing the measurement for the DUT logic feature to an evaluation criterion to form result information, the evaluation criterion defined by the semiconductor specification, and determining whether the DUT logic feature meets the evaluation criterion of the semiconductor specification based on the result information.

The method may also include generating a test report to indicate whether the DUT logic feature passes the semiconductor testing and is in compliance with the semiconductor specification, or fails the semiconductor testing and is not in compliance with the semiconductor specification.

The method may also include receiving the logic feature from a graphical user interface (GUI).

The method may also include receiving a selection of a test script to test the logic feature from a graphical user interface (GUI).

The method may also include executing a test script to test the logic feature, the test script to generate the control signal to initiate the semiconductor testing.

The method may also include where the logic feature is defined by the semiconductor specification, the semiconductor specification to comprise a die-to-die (D2D) on-package interconnect specification.

The method may also include where the logic feature is defined by the semiconductor specification, the semiconductor specification to comprise a universal chiplet interconnect express (UCIe) specification.

The method may also include where the model chiplet includes logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the DUT chiplet.

The method may also include where the model chiplet includes an adapter, the adapter to include a compliance flow control unit (FCU) level interface transfer (FLIT) injector, the compliance FLIT injector to generate a set of test FLITs in a test pattern to test the DUT chiplet.

The method may also include where the DUT chiplet includes a test interface, the DUT logic feature and DUT test logic, the DUT logic feature to comprise an unknown model for the logic feature in accordance with a semiconductor specification, the DUT test logic to receive the test information over the interconnect, generate the response information associated with the DUT logic feature, and send the response information over the interconnect to the model chiplet.

The method may also include where the DUT chiplet includes logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the model chiplet. Other technical features may be readily apparent to one skilled in the art from the following figures, descriptions, and claims.

It is emphasized that the Abstract of the Disclosure is provided to allow a reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment. In the appended claims, the terms “including” and “in which” are used as the plain-English equivalents of the respective terms “comprising” and “wherein,” respectively. Moreover, the terms “first,” “second,” “third,” and so forth, are used merely as labels, and are not intended to impose numerical requirements on their objects.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An apparatus, comprising:
a model chiplet for semiconductor testing, the model chiplet having a test interface, a model logic feature and model test logic, the model logic feature to comprise a known good model (KGM) for a logic feature defined by a semiconductor specification, the model test logic to:
receive a control signal from the test interface, the control signal to initiate testing of a device under test (DUT) logic feature of a DUT chiplet;
send test information over an interconnect in response to the control signal, the test information designed to test the DUT logic feature of the DUT chiplet;
receive response information over the interconnect in response to the test information, the response information associated with the DUT logic feature of the DUT chiplet;
generate a measurement for the DUT logic feature based on the response information; and
send the measurement for the DUT logic feature to the test interface.

2. The apparatus of claim 1, wherein the logic feature is defined by a semiconductor specification, the semiconductor specification to comprise a universal chiplet interconnect express (UCIe) specification.

3. The apparatus of claim 1, the model chiplet having logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the DUT chiplet.

4. The apparatus of claim 1, the model chiplet having an adapter, the adapter to include a compliance flow control unit (FCU) level interface transfer (FLIT) injector, the compliance FLIT injector to generate a set of test FLITs in a test pattern to test the DUT chiplet.

5. The apparatus of claim 1, the model test logic to comprise a pattern generator, a loopback generator, a droop detector, a process monitor, an oscilliscope, or a ring oscillator.

6. The apparatus of claim 1, the DUT chiplet having a test interface, the DUT logic feature and DUT test logic, the DUT logic feature to comprise an unknown model for the logic feature in accordance with a semiconductor specification, the DUT test logic to receive the test information over the interconnect, generate the response information associated with the DUT logic feature, and send the response information over the interconnect to the model chiplet.

7. The apparatus of claim 1, the DUT chiplet having logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the model chiplet.

8. The apparatus of claim 1, the DUT chiplet having an adapter, the adapter to include a compliance flow control unit (FCU) level interface transfer (FLIT) injector, the compliance FLIT injector to generate a set of test FLITs in a test pattern to test the DUT chiplet.

9. The apparatus of claim 1, the DUT chiplet having DUT test logic, the DUT test logic to comprise a compliance manager, a header manager, a pattern generator, a state manager, a protocol manager, or a graph manager.

10. A system, comprising:
circuitry to manage semiconductor testing, the circuitry arranged to:
send a control signal to a model chiplet to initiate semiconductor testing, the model chiplet to comprise a model logic feature that is a known good model (KGM) of a logic feature defined by a semiconductor specification;
receive a measurement from the model chiplet in response to the control signal to initiate semiconductor testing, the measurement associated with a device under testing (DUT) logic feature of a DUT chiplet, the DUT logic feature to comprise an unknown good model (UGM) of the logic feature defined by the semiconductor specification;
compare the measurement for the DUT logic feature to an evaluation criterion to form result information, the evaluation criterion defined by the semiconductor specification; and
determine whether the DUT logic feature meets the evaluation criterion of the semiconductor specification based on the result information.

11. The system of claim 10, wherein the logic feature is defined by the semiconductor specification, the semiconductor specification to comprise a universal chiplet interconnect express (UCIe) specification.

12. The system of claim 10, comprising a set of test connections communicatively coupled to the test device and a test package, the test package to comprise the model chiplet, the DUT chiplet and an interconnect to transmit signals between the model chiplet and the DUT chiplet, the test package to comprise a standard test package or an advanced test package.

13. The system of claim 10, comprising a test package coupled to the test device via a test connection, the test package having the model chiplet, the DUT chiplet and an interconnect to transmit signals between the model chiplet and the DUT chiplet, the test package to comprise a standard test package or an advanced test package.

14. The system of claim 10, comprising the model chiplet, the a model chiplet for semiconductor testing, the model chiplet having a test interface, a model logic feature and model test logic, the model logic feature to comprise a known good model (KGM) for a logic feature defined by a semiconductor specification.

15. The system of claim 10, comprising the model chiplet having logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the DUT chiplet.

16. The system of claim 10, comprising the model chiplet having an adapter, the adapter to include a compliance flow control unit (FCU) level interface transfer (FLIT) injector, the compliance FLIT injector to generate a set of test FLITs in a test pattern to test the DUT chiplet.

17. The system of claim 10, comprising the model test logic to comprise a pattern generator, a loopback generator, a droop detector, a process monitor, an oscilliscope, or a ring oscillator.

18. A method, comprising:
sending a control signal to a model chiplet to initiate semiconductor testing, the model chiplet to comprise a model logic feature that is a known good model (KGM) of a logic feature defined by a semiconductor specification;
receiving a measurement from the model chiplet in response to the control signal to initiate semiconductor testing, the measurement associated with a device under testing (DUT) logic feature of a DUT chiplet, the DUT logic feature to comprise an unknown good model (UGM) of the logic feature defined by the semiconductor specification;
comparing the measurement for the DUT logic feature to an evaluation criterion to form result information, the evaluation criterion defined by the semiconductor specification; and
determining whether the DUT logic feature meets the evaluation criterion of the semiconductor specification based on the result information.

19. The method of claim 18, comprising generating a test report to indicate whether the DUT logic feature passes the semiconductor testing and is in compliance with the semiconductor specification, or fails the semiconductor testing and is not in compliance with the semiconductor specification.

20. The method of claim 18, wherein the model chiplet includes logic for a physical layer, an adapter and a protocol layer for an interconnect, the adapter to receive flow control unit (FCU) level interface transfer (FLIT) aware die-to-die (D2D) interface (FDI) data from the protocol layer, and output raw D2D interface (RDI) data to the physical layer for transport over the interconnect to the DUT chiplet.
